(19) United States
(12) Patent Application Publication
(10) Pub. No.: US 2024/0079998 A1
(43) Pub. Date: Mar. 7, 2024

(54) COMBINERS FOR DOHERTY POWER AMPLIFIER SYSTEMS

(71) Applicant: Skyworks Solutions, Inc., Irvine, CA (US)

(72) Inventors: Serge Francois Drogi, Flagstaff, AZ (US); Aleksey A. Lyalin, Moorpark, CA (US)

(21) Appl. No.: 18/461,829

(22) Filed: Sep. 6, 2023

Related U.S. Application Data
(60) Provisional application No. 63/374,824, filed on Sep. 7, 2022.

(51) Int. Cl. H03F 1/02; H03F 3/21

(52) U.S. Cl. CPC H03F 1/0288; H03F 3/211; H03F 2200/09; H03F 2200/451

(57) ABSTRACT

Combiners for Doherty power amplifier systems are provided herein. In certain embodiments, a combiner structure includes a first balun combiner for combining an output of a first auxiliary amplifier and a second auxiliary amplifier, and a second balun combiner for combining the output of a main amplifier and an output of the first balun combiner. Each combiner can include a balun having a first conductor connected between a first input port and an output port, a second conductor connected between an isolated node and a second input port and magnetically coupled to the first conductor. An isolation capacitor is connected between the first input port and the isolated node, and an output capacitor is connected between the second input port and the output port. In certain implementations, the balun combiner further includes a termination capacitor between the isolated node and ground.

### CROSS-REFERENCE TO RELATED APPLICATIONS

This application claims the benefit of priority under 35 U.S.C. § 119 of U.S. Provisional Patent Application No. 63/374,824, filed Sep. 7, 2022 and titled “COMBINERS FOR DOHERTY POWER AMPLIFIER SYSTEMS,” which is herein incorporated by reference in its entirety.

### BACKGROUND

### Field

Embodiments of the invention relate to electronic systems, and in particular, to power amplifiers for use in radio frequency (RF) electronics.

### Description of the Related Technology

Power amplifiers are used in radio frequency (RF) communication systems to amplify RF signals for transmission via antennas. It is important to manage the power of RF signal transmissions to prolong battery life and/or provide a suitable transmit power level.

Examples of RF communication systems with one or more power amplifiers include, but are not limited to, mobile phones, tablets, base stations, network access points, customer-premises equipment (CPE), laptops, and wearable electronics. For example, in wireless devices that communicate using a cellular standard, a wireless local area network (WLAN) standard, and/or any other suitable communication standard, a power amplifier can be used for RF signal amplification. An RF signal can have a frequency in the range of about 30 kHz to 300 GHz, such as in the range of about 400 MHz to about 7.125 GHz for Frequency Range 1 (FR1) of the Fifth Generation (5G) communication standard or in the range of about 24.250 GHz to about 71.000 GHz for Frequency Range 2 (FR2) of the 5G communication standard.

### SUMMARY

In certain embodiments, the present disclosure relates to a Doherty power amplifier system. The Doherty power amplifier system includes an input splitting circuit configured to split a radio frequency input signal into a plurality of radio frequency input signals including a first radio frequency input signal, a second radio frequency input signal, and a third radio frequency input signal. The Doherty power amplifier system further includes a plurality of amplifiers including a main amplifier configured to amplify the first radio frequency input signal to generate a first radio frequency output signal, a first auxiliary amplifier configured to amplify the second radio frequency input signal to generate a second radio frequency output signal, and a second auxiliary amplifier configured to amplify the third radio frequency input signal to generate a third radio frequency output signal. The Doherty power amplifier system further includes a bias circuit configured to receive an envelope signal indicating an envelope of the radio frequency input signal, and to control both a first biasing signal of the first auxiliary amplifier and a second biasing signal of the second auxiliary amplifier based on the envelope signal.

In various embodiments, the bias circuit controls the first biasing signal and the second biasing signal to set a state of the Doherty power amplifier system. According to a number of embodiments, the state is selected from a plurality of states including a first state in which the first auxiliary amplifier and the second auxiliary amplifier are both disabled, a second state in which the first auxiliary amplifier is enabled and the second auxiliary amplifier is disabled, and a third state in which the first auxiliary amplifier and the second auxiliary amplifier are both enabled. In accordance with several embodiments, the bias circuit is configured to select the first state when the envelope signal indicates a signal power of the radio frequency input signal is less than a first threshold. According to some embodiments, the bias circuit is configured to select the second state when the envelope signal indicates the signal power is greater than or equal to the first threshold but less than a second threshold, and to select the third state when the envelope signal indicates the signal power is greater than or equal to the second threshold.

In several embodiments, the main amplifier, the first auxiliary amplifier, and the second auxiliary amplifier have a common amplifier topology. According to various embodiments, the main amplifier, the first auxiliary amplifier, and the second auxiliary amplifier have about equal size.

In some embodiments, the main amplifier, the first auxiliary amplifier, and the second auxiliary amplifier are powered by a common power supply voltage. According to several embodiments, the common power supply voltage is fixed.

In various embodiments, the envelope signal is a differential analog signal.

In several embodiments, envelope signal is outputted from a discrete look-up table.

In some embodiments, the Doherty power amplifier system further includes an output combining circuit configured to generate a radio frequency output signal based on combining the first radio frequency output signal, the second radio frequency output signal, and third radio frequency output signal.

In various embodiments, the first radio frequency input signal is phase-delayed by about ninety degrees relative to the second radio frequency input signal. According to a number of embodiments, the third radio frequency input signal is phase-delayed by about ninety degrees relative to the second radio frequency input signal.

In certain embodiments, the present disclosure relates to a method of radio frequency signal amplification. The method includes splitting a radio frequency input signal into a first radio frequency input signal, a second radio frequency input signal, and a third radio frequency input signal using an input splitting circuit. The method further includes amplifying the first radio frequency input signal to generate a first radio frequency output signal using a main amplifier, amplifying the second radio frequency input signal to generate a second radio frequency output signal using a first auxiliary amplifier, amplifying the third radio frequency input signal to generate a third radio frequency output signal using a second auxiliary amplifier, and controlling both a first biasing signal of the first auxiliary amplifier and a second biasing signal of the second auxiliary amplifier based on an envelope signal using a biasing circuit, the envelope signal indicating an envelope of the radio frequency input signal.

In various embodiments, controlling the first biasing signal and the second biasing signal to set a state of the Doherty power amplifier system. According to a number of embodiments, the method further includes selecting the state from a plurality of states including a first state in which the first auxiliary amplifier and the second auxiliary amplifier are both disabled, a second state in which the first auxiliary amplifier is enabled and the second auxiliary amplifier is disabled, and a third state in which the first auxiliary amplifier and the second auxiliary amplifier are both enabled. In accordance with some embodiments, the method further includes selecting the first state when the envelope signal indicates a signal power of the radio frequency input signal is less than a first threshold. According to several embodiments, the method further includes selecting the second state when the envelope signal indicates the signal power is greater than or equal to the first threshold but less than a second threshold, and selecting the third state when the envelope signal indicates the signal power is greater than or equal to the second threshold.

In some embodiments, the method further includes generating a radio frequency output signal based on combining the first radio frequency output signal, the second radio frequency output signal, and third radio frequency output signal using an output combining circuit.

In certain embodiments, the present disclosure relates to a radio frequency communication system. The radio frequency communication system includes a transceiver configured to generate a radio frequency input signal and an envelope signal indicating an envelope of the radio frequency input signal, and a front end system including a Doherty power amplifier system configured to amplify the radio frequency input signal. The Doherty power amplifier system includes an input splitting circuit configured to split the radio frequency input signal into a first radio frequency input signal, a second radio frequency input signal, and a third radio frequency input signal. The Doherty power amplifier system further includes a main amplifier configured to amplify the first radio frequency input signal to generate a first radio frequency output signal, a first auxiliary amplifier configured to amplify the second radio frequency input signal to generate a second radio frequency output signal, a second auxiliary amplifier configured to amplify the third radio frequency input signal to generate a third radio frequency output signal, and a bias circuit configured to control both a first biasing signal of the first auxiliary amplifier and a second biasing signal of the second auxiliary amplifier based on the envelope signal.

In some embodiments, the bias circuit controls the first biasing signal and the second biasing signal to control a state of the Doherty power amplifier system. According to several embodiments, the state is selected from a plurality of states including a first state in which the first auxiliary amplifier and the second auxiliary amplifier are both disabled, a second state in which the first auxiliary amplifier is enabled and the second auxiliary amplifier is disabled, and a third state in which the first auxiliary amplifier and the second auxiliary amplifier are both enabled. In accordance with various embodiments, the bias circuit is configured to select the first state when the envelope signal indicates a signal power of the radio frequency input signal is less than a first threshold. According to a number of embodiments, the bias circuit is configured to select the second state when the envelope signal indicates the signal power is greater than or equal to the first threshold but less than a second threshold, and to select the third state when the envelope signal indicates the signal power is greater than or equal to the second threshold.

In various embodiments, the main amplifier, the first auxiliary amplifier, and the second auxiliary amplifier have a common amplifier topology. According to a number of embodiments, the main amplifier, the first auxiliary amplifier, and the second auxiliary amplifier have about equal size.

In several embodiments, the main amplifier, the first auxiliary amplifier, and the second auxiliary amplifier are powered by a common power supply voltage. According to a number of embodiments, the common power supply voltage is fixed.

In various embodiments, the envelope signal is a differential analog signal.

In some embodiments, the envelope signal is outputted from a discrete look-up table.

In several embodiments, the Doherty power amplifier system further includes an output combining circuit configured to generate a radio frequency output signal based on combining the first radio frequency output signal, the second radio frequency output signal, and third radio frequency output signal.

In various embodiments, the first radio frequency input signal is phase-delayed by about ninety degrees relative to the second radio frequency input signal. According to a number of embodiments, the third radio frequency input signal is phase-delayed by about ninety degrees relative to the second radio frequency input signal.

In certain embodiments, the present disclosure relates to a Doherty power amplifier system. The Doherty power amplifier system includes a plurality of amplifiers including a main amplifier configured to amplify a first radio frequency input signal to generate a first radio frequency output signal, a first auxiliary amplifier configured to amplify a second radio frequency input signal to generate a second radio frequency output signal, and a second auxiliary amplifier configured to amplify a third radio frequency input signal to generate a third radio frequency output signal. The Doherty power amplifier system further includes a first balun combiner configured to combine the second radio frequency output signal and the third radio frequency output signal to generate a first radio frequency combined signal, and a second balun combiner configured to combine the first radio frequency output signal and the first radio frequency combined signal to generate a second radio frequency combined signal, the second balun combiner having an impedance ratio different than an impedance ratio of the first balun combiner.

In some embodiments, the Doherty power amplifier system further includes a bias circuit configured to selectively turn on or off the first auxiliary amplifier and the second auxiliary amplifier based on an envelope signal.

In various embodiments, the impedance ratio of the second balun combiner is greater than the impedance ratio of the first balun combiner. According to a number of embodiments, the impedance ratio of the first balun combiner is about three to one. In accordance with several embodiments, the impedance ratio of the second balun combiner is about two to one.

In some embodiments, the Doherty power amplifier system further includes an input splitting circuit configured to split a radio frequency input signal into the first radio frequency input signal, the second radio frequency input signal, and the third radio frequency input signal.

In several embodiments, the first radio frequency input signal lags the second radio frequency input signal by about ninety degrees.

In various embodiments, the third radio frequency input signal lags the second radio frequency input signal by about ninety degrees.

In some embodiments, the first balun combiner includes a first input port that receives the second radio frequency output signal, a second input port that receives the third radio frequency output signal, an output port that provides the first radio frequency combined signal, an isolation capacitor connected between the first input port and an isolated node, an output capacitor connected between the second input port and the output port, and a balun having a first conductor connected between the first input port and the output port and a second conductor connected between the isolated node and the second input port. According to a number of embodiments, the first balun combiner further includes a termination capacitor connected between the isolated node and ground. In accordance with several embodiments, the first balun combiner further includes a third conductor connected in parallel with the second conductor, the second conductor and the third conductor each magnetically coupled to the first conductor. According to various embodiments, the second conductor and the third conductor are magnetically coupled to the first conductor with opposite coupling polarity.

In certain embodiments, the present disclosure relates to a method of radio frequency signal amplification. The method includes amplifying a first radio frequency input signal to generate a first radio frequency output signal using a main amplifier, amplifying a second radio frequency input signal to generate a second radio frequency output signal using a first auxiliary amplifier, amplifying a third radio frequency input signal to generate a third radio frequency output signal using a second auxiliary amplifier, combining the second radio frequency output signal and the third radio frequency output signal to generate a first radio frequency combined signal using a first balun combiner, and combining the first radio frequency output signal and the first radio frequency combined signal to generate a second radio frequency combined signal using a second balun combiner, the second balun combiner having an impedance ratio different than an impedance ratio of the first balun combiner.

In various embodiments, the method further includes selectively turning on or off the first auxiliary amplifier and the second auxiliary amplifier based on an envelope signal using a bias circuit.

In certain embodiments, the present disclosure relates to a radio frequency communication system. The radio frequency communication system includes a front end system including a main amplifier configured to amplify a first radio frequency input signal to generate a first radio frequency output signal, a first auxiliary amplifier configured to amplify a second radio frequency input signal to generate a second radio frequency output signal, a second auxiliary amplifier configured to amplify a third radio frequency input signal to generate a third radio frequency output signal, a first balun combiner configured to combine the second radio frequency output signal and the third radio frequency output signal to generate a first radio frequency combined signal, and a second balun combiner configured to combine the first radio frequency output signal and the first radio frequency combined signal to generate a second radio frequency combined signal, the second balun combiner having an impedance ratio different than an impedance ratio of the first balun combiner. The radio frequency communication system further includes an antenna configured to transmit the second radio frequency combined signal.

In some embodiments, the front end system further includes a bias circuit configured to selectively turn on or off the first auxiliary amplifier and the second auxiliary amplifier based on an envelope signal.

In several embodiments, the impedance ratio of the second balun combiner is greater than the impedance ratio of the first balun combiner.

In various embodiments, the front end system includes an input splitting circuit configured to split a radio frequency input signal into the first radio frequency input signal, the second radio frequency input signal, and the third radio frequency input signal. According to a number of embodiments, the radio frequency communication system further includes a transceiver configured to generate the radio frequency input signal.

In some embodiments, the first balun combiner includes a first input port that receives the second radio frequency output signal, a second input port that receives the third radio frequency output signal, an output port that provides the first radio frequency combined signal, an isolation capacitor connected between the first input port and an isolated node, an output capacitor connected between the second input port and the output port, and a balun having a first conductor connected between the first input port and the output port and a second conductor connected between the isolated node and the second input port.

### BRIEF DESCRIPTION OF THE DRAWINGS

FIG. 1 is a schematic diagram of one example of a communication network.

FIG. 2A is a schematic diagram of one example of a downlink channel using multi-input and multi-output (MIMO) communications.

FIG. 2B is schematic diagram of one example of an uplink channel using MIMO communications.

FIG. 3 is a schematic diagram of one embodiment of a mobile device.

FIG. 4 is a schematic diagram of one embodiment of a transmit system for transmitting radio frequency (RF) signals.

FIG. 5 illustrates an example of a 2-way Doherty power amplifier.

FIG. 6 illustrates an example of a 3-way Doherty power amplifier.

FIG. 7 illustrates one embodiment of a 3-way Doherty power amplifier.

FIG. 8A is a schematic diagram of one embodiment of a Doherty power amplifier system.

FIG. 8B is a schematic diagram of another embodiment of a Doherty power amplifier system.

FIG. 9 illustrates an example of experimental data representing improved efficiency for one implementation of the Doherty power amplifier system of FIG. 8A.

FIG. 10 is a schematic diagram of one embodiment of a transmit system for a mobile device.

FIG. 11 is a schematic diagram of another embodiment of a transmit system for a mobile device.

FIG. 12 is a schematic diagram of one embodiment of an envelope tracking transmit system.

FIG. 13 is a schematic diagram of one embodiment of a balun combiner for a Doherty power amplifier system.

FIG. 14 illustrates impedance trajectories resulting from Doherty action in the balun combiner of FIG. 13.

FIG. 15 is a schematic diagram of another embodiment of a balun combiner for a Doherty power amplifier system.

FIG. 16 illustrates impedance trajectories resulting from Doherty action in the balun combiner of FIG. 15.

FIG. 17 is a schematic diagram of one embodiment of Doherty combiner circuitry for three-way combining.

FIG. 18A illustrates the modification of impedance presented to the main amplifier of the configuration of FIG. 17.

FIG. 18B illustrates the modification of impedance presented to the first auxiliary amplifier of the configuration of FIG. 17.

FIG. 19A is a schematic diagram of one embodiment of a packaged module.

FIG. 19B is a schematic diagram of a cross-section of the packaged module of FIG. 19A taken along the lines 19B-19B.

FIG. 20 is a schematic diagram of one embodiment of a phone board.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The International Telecommunication Union (ITU) is a specialized agency of the United Nations (UN) responsible for global issues concerning information and communication technologies, including the shared global use of radio spectrum.

The 3rd Generation Partnership Project (3GPP) is a collaboration between groups of telecommunications standard bodies across the world, such as the Association of Radio Industries and Businesses (ARIB), the Telecommunications Technology Committee (TTC), the China Communications Standards Association (CCSA), the Alliance for Telecommunications Industry Solutions (ATIS), the Telecommunications Technology Association (TTA), the European Telecommunications Standards Institute (ETSI), and the Telecommunications Standards Development Society, India (TSDSI).

Working within the scope of the ITU, 3GPP develops and maintains technical specifications for a variety of mobile communication technologies, including, for example, second generation (2G) technology (for instance, Global System for Mobile Communications (GSM) and Enhanced Data Rates for GSM Evolution (EDGE)), third generation (3G) technology (for instance, Universal Mobile Telecommunications System (UMTS) and High Speed Packet Access (HSPA)), and fourth generation (4G) technology (for instance, Long Term Evolution (LTE) and LTE-Advanced).

The technical specifications controlled by 3GPP can be expanded and revised by specification releases, which can span multiple years and specify a breadth of new features and evolutions.

In one example, 3GPP introduced carrier aggregation (CA) for LTE in Release 10. Although initially introduced with two downlink carriers, 3GPP expanded carrier aggregation in Release 14 to include up to five downlink carriers and up to three uplink carriers. Other examples of new features and evolutions provided by 3GPP releases include, but are not limited to, License Assisted Access (LAA), enhanced LAA (eLAA), Narrowband Internet of things (NB-IOT), Vehicle-to-Everything (V2X), and High Power User Equipment (HPUE).

3GPP introduced Phase 1 of fifth generation (5G) technology in Release 15, and introduced Phase 2 of 5G technology in Release 16. Subsequent 3GPP releases will further evolve and expand 5G technology. 5G technology is also referred to herein as 5G New Radio (NR).

5G NR supports or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR.

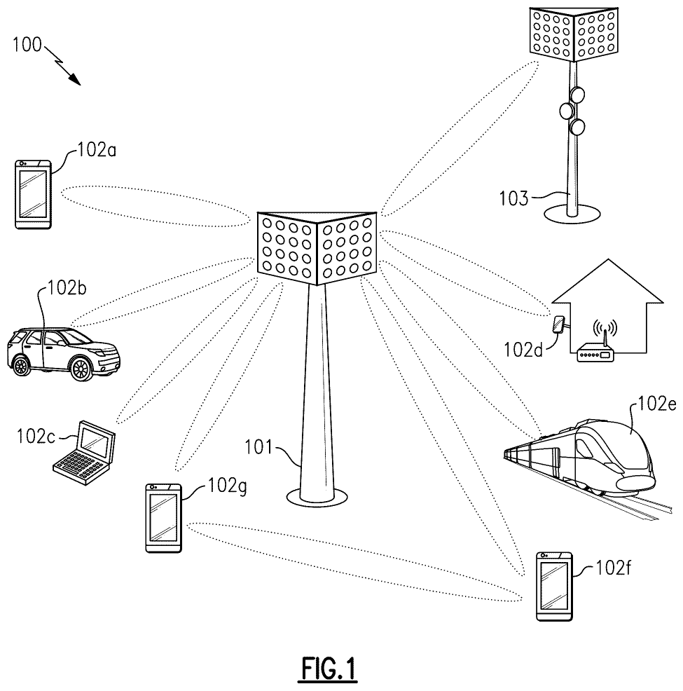

FIG. 1 is a schematic diagram of one example of a communication network 100. The communication network 100 includes a macro cell base station 101, a small cell base station 103, and various examples of user equipment (UE), including a first mobile device 102a, a wireless-connected car 102b, a laptop 102c, a stationary wireless device 102d, a wireless-connected train 102e, a second mobile device 102f, and a third mobile device 102g. One or more of the base stations and/or user equipment can be implemented with Doherty power amplifiers in accordance with the teachings herein.

Although specific examples of base stations and user equipment are illustrated in FIG. 1, a communication network can include base stations and user equipment of a wide variety of types and/or numbers.

For instance, in the example shown, the communication network 100 includes the macro cell base station 101 and the small cell base station 103. The small cell base station 103 can operate with relatively lower power, shorter range, and/or with fewer concurrent users relative to the macro cell base station 101. The small cell base station 103 can also be referred to as a femtocell, a picocell, or a microcell. Although the communication network 100 is illustrated as including two base stations, the communication network 100 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 100 of FIG. 1 supports communications using a variety of cellular technologies, including, for example, 4G LTE and 5G NR. In certain implementations, the communication network 100 is further adapted to provide a wireless local area network (WLAN), such as WiFi. Although various examples of communication technologies have been provided, the communication network 100 can be adapted to support a wide variety of communication technologies.

Various communication links of the communication network 100 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 100 can be implemented to support self-fronthaul and/or self-backhaul (for instance, as between mobile device 102g and mobile device 1020.

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1), Frequency Range 2 (FR2), or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz. Cellular user equipment can communicate using beamforming and/or other techniques over a wide range of frequencies, including, for example, FR2-1 (24 GHz to 52 GHz), FR2-2 (52 GHz to 71 GHz), and/or FR1 (400 MHz to 7125 MHz).

Different users of the communication network 100 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 100 of FIG. 1 can be used to support a wide variety of advanced communication features, including, but not limited to, eMBB, uRLLC, and/or mMTC.

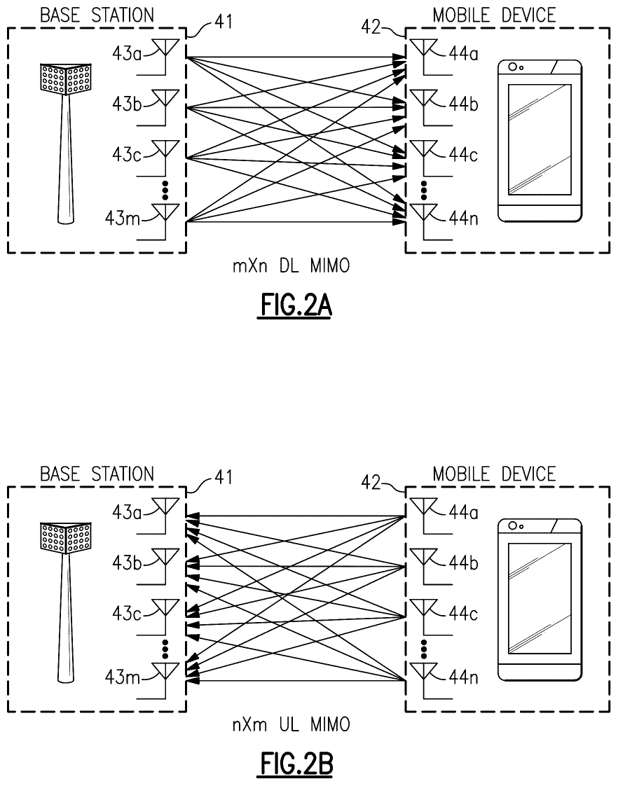

FIG. 2A is a schematic diagram of one example of a downlink channel using multi-input and multi-output (MIMO) communications. FIG. 2B is a schematic diagram of one example of an uplink channel using MIMO communications.

MIMO communications use multiple antennas for simultaneously communicating multiple data streams over common frequency spectrum. In certain implementations, the data streams operate with different reference signals to enhance data reception at the receiver. MIMO communications benefit from higher SNR, improved coding, and/or reduced signal interference due to spatial multiplexing differences of the radio environment.

MIMO order refers to a number of separate data streams sent or received. For instance, MIMO order for downlink communications can be described by a number of transmit antennas of a base station and a number of receive antennas for UE, such as a mobile device. For example, two-by-two (2×2) DL MIMO refers to MIMO downlink communications using two base station antennas and two UE antennas. Additionally, four-by-four (4×4) DL MIMO refers to MIMO downlink communications using four base station antennas and four UE antennas.

In the example shown in FIG. 2A, downlink MIMO communications are provided by transmitting using M antennas 43a, 43b, 43c, . . . 43m of the base station 41 and receiving using N antennas 44a, 44b, 44c, . . . 44n of the mobile device 42. Accordingly, FIG. 2A illustrates an example of m×n DL MIMO.

Likewise, MIMO order for uplink communications can be described by a number of transmit antennas of UE, such as a mobile device, and a number of receive antennas of a base station. For example, 2×2 UL MIMO refers to MIMO uplink communications using two UE antennas and two base station antennas. Additionally, 4×4 UL MIMO refers to MIMO uplink communications using four UE antennas and four base station antennas.

In the example shown in FIG. 2B, uplink MIMO communications are provided by transmitting using N antennas 44a, 44b, 44c, . . . 44n of the mobile device 42 and receiving using M antennas 43a, 43b, 43c, . . . 43m of the base station 41. Accordingly, FIG. 2B illustrates an example of n×m UL MIMO.

By increasing the level or order of MIMO, bandwidth of an uplink channel and/or a downlink channel can be increased.

MIMO communications are applicable to communication links of a variety of types, such as FDD communication links and TDD communication links.

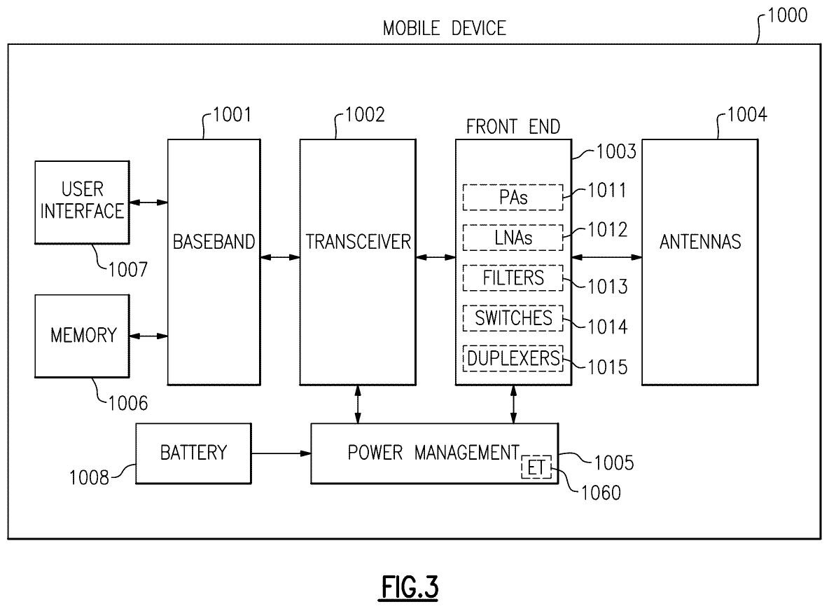

FIG. 3 is a schematic diagram of one example of a mobile device 1000. The mobile device 1000 includes a baseband system 1001, a transceiver 1002, a front end system 1003, antennas 1004, a power management system 1005, a memory 1006, a user interface 1007, and a battery 1008.

The mobile device 1000 can be used communicate using a wide variety of communications technologies, including, but not limited to, 2G, 3G, 4G (including LTE, LTE-Advanced, and LTE-Advanced Pro), 5G, WLAN (for instance, Wi-Fi), WPAN (for instance, Bluetooth and ZigBee), WMAN (for instance, WiMax), and/or GPS technologies.

The transceiver 1002 generates RF signals for transmission and processes incoming RF signals received from the antennas 1004. It will be understood that various functionalities associated with the transmission and receiving of RF signals can be achieved by one or more components that are collectively represented in FIG. 3 as the transceiver 1002. In one example, separate components (for instance, separate circuits or dies) can be provided for handling certain types of RF signals.

The front end system 1003 aids in conditioning signals transmitted to and/or received from the antennas 1004. In the illustrated embodiment, the front end system 1003 includes power amplifiers (PAs) 1011, low noise amplifiers (LNAs) 1012, filters 1013, switches 1014, and duplexers 1015. However, other implementations are possible.

For example, the front end system 1003 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

One or more of the power amplifiers 1011 can be Doherty power amplifiers implemented in accordance with the teachings herein.

In certain implementations, the mobile device 1000 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band and/or in different bands.

The antennas 1004 can include antennas used for a wide variety of types of communications. For example, the antennas 1004 can include antennas associated transmitting and/or receiving signals associated with a wide variety of frequencies and communications standards.

In certain implementations, the antennas 1004 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 1000 can operate with beamforming in certain implementations. For example, the front end system 1003 can include phase shifters having variable phase controlled by the transceiver 1002. Additionally, the phase shifters are controlled to provide beam formation and directivity for transmission and/or reception of signals using the antennas 1004. For example, in the context of signal transmission, the phases of the transmit signals provided to the antennas 1004 are controlled such that radiated signals from the antennas 1004 combine using constructive and destructive interference to generate an aggregate transmit signal exhibiting beam-like qualities with more signal strength propagating in a given direction. In the context of signal reception, the phases are controlled such that more signal energy is received when the signal is arriving to the antennas 1004 from a particular direction. In certain implementations, the antennas 1004 include one or more arrays of antenna elements to enhance beamforming.

The baseband system 1001 is coupled to the user interface 1007 to facilitate processing of various user input and output (I/O), such as voice and data. The baseband system 1001 provides the transceiver 1002 with digital representations of transmit signals, which the transceiver 1002 processes to generate RF signals for transmission. The baseband system 1001 also processes digital representations of received signals provided by the transceiver 1002. As shown in FIG. 3, the baseband system 1001 is coupled to the memory 1006 of facilitate operation of the mobile device 1000.

The memory 1006 can be used for a wide variety of purposes, such as storing data and/or instructions to facilitate the operation of the mobile device 1000 and/or to provide storage of user information.

The power management system 1005 provides a number of power management functions of the mobile device 1000. The power management system 1005 of FIG. 3 includes an envelope tracker 1060. As shown in FIG. 3, the power management system 1005 receives a battery voltage form the battery 1008. The battery 1008 can be any suitable battery for use in the mobile device 1000, including, for example, a lithium-ion battery.

The mobile device 1000 of FIG. 3 illustrates one example of an RF communication system that can include power amplifier(s) implemented in accordance with one or more features of the present disclosure. However, the teachings herein are applicable to RF communication systems implemented in a wide variety of ways.

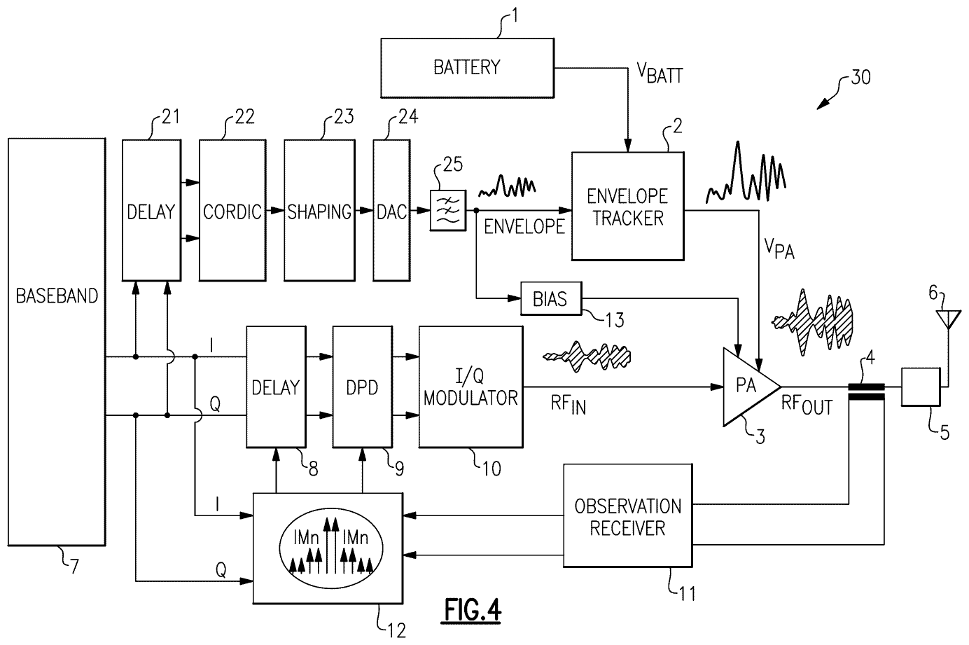

FIG. 4 is a schematic diagram of one embodiment of a transmit system 30 for transmitting RF signals from a mobile device, a base station, or other RF communication system. The transmit system 30 includes a battery 1, an envelope tracker 2, a power amplifier 3, a directional coupler 4, a duplexing and/or switching circuit 5, an antenna 6, a baseband processor 7, a signal delay circuit 8, a digital pre-distortion (DPD) circuit 9, an I/Q modulator 10, an observation receiver 11, an intermodulation detection circuit 12, a bias circuit 13, an envelope delay circuit 21, a coordinate rotation digital computation (CORDIC) circuit 22, a shaping circuit 23, a digital-to-analog converter (DAC) 24, and a reconstruction filter 25.

The transmit system 30 of FIG. 4 illustrates one example of an RF communication system that can include Doherty power amplifier(s) implemented in accordance with one or more features of the present disclosure. However, the teachings herein are applicable to RF communication systems implemented in a wide variety of ways.

The baseband processor 7 operates to generate an I signal and a Q signal, which correspond to signal components of a sinusoidal wave or signal of a desired amplitude, frequency, and phase. For example, the I signal can be used to represent an in-phase component of the sinusoidal wave and the Q signal can be used to represent a quadrature-phase component of the sinusoidal wave, which can be an equivalent representation of the sinusoidal wave. In certain implementations, the I and Q signals are provided to the I/Q modulator 10 in a digital format. The baseband processor 7 can be any suitable processor configured to process a baseband signal. For instance, the baseband processor 7 can include a digital signal processor, a microprocessor, a programmable core, or any combination thereof.

The signal delay circuit 8 provides adjustable delay to the I and Q signals to aid in controlling relative alignment between the envelope signal and the RF signal RF_{IN}. The amount of delay provided by the signal delay circuit 8 is controlled based on amount of intermodulation detected by the intermodulation detection circuit 12.

The DPD circuit 9 operates to provide digital shaping to the delayed I and Q signals from the signal delay circuit 8 to generate digitally pre-distorted I and Q signals. In the illustrated embodiment, the DPD provided by the DPD circuit 9 is controlled based on amount of intermodulation detected by the intermodulation detection circuit 12. The DPD circuit 9 serves to reduce a distortion of the power amplifier 3 and/or to increase the efficiency of the power amplifier 3. The DPD circuit 9 is configured to generate digitally pre-distorted I and Q signals.

The I/Q modulator 10 receives the digitally pre-distorted I and Q signals, which are processed to generate the RF signal RF_{IN}. For example, the I/Q modulator 10 can include DACs configured to convert the digitally pre-distorted I and Q signals into an analog format, mixers for upconverting the analog I and Q signals to radio frequency, and a signal combiner for combining the upconverted I and Q signals into an RF signal suitable for amplification by the power amplifier 3. In certain implementations, the I/Q modulator 10 can include one or more filters configured to filter frequency content of signals processed therein.

The envelope delay circuit 21 delays the I and Q signals from the baseband processor 7. Additionally, the CORDIC circuit 22 processes the delayed I and Q signals to generate a digital envelope signal representing an envelope of the RF signal RF_{IN}. Although FIG. 4 illustrates an implementation using the CORDIC circuit 22, an envelope signal can be obtained in other ways.

The shaping circuit 23 operates to shape the digital envelope signal to enhance the performance of the transmit system 30. In certain implementations, the shaping circuit 23 includes a shaping table that maps each level of the digital envelope signal to a corresponding shaped envelope signal level. Envelope shaping can aid in controlling linearity, distortion, and/or efficiency of the power amplifier 3.

In the illustrated embodiment, the shaped envelope signal is a digital signal that is converted by the DAC 24 to an analog envelope signal. Additionally, the analog envelope signal is filtered by the reconstruction filter 25 to generate an envelope signal suitable for use by the envelope tracker 2. In certain implementations, the reconstruction filter 25 includes a low pass filter.

With continuing reference to FIG. 4, the envelope tracker 2 receives the envelope signal from the reconstruction filter 25 and a battery voltage V_{BATT} from the battery 1, and uses the envelope signal to generate a power amplifier supply voltage V_{PA} for the power amplifier 3 that changes in relation to the envelope of the RF signal RF_{IN}. The power amplifier 3 receives the RF signal RF_{IN} from the I/Q modulator 10, and provides an amplified RF signal R_{FOUT} to the antenna 6 through the duplexing and switching circuit 5, in this example.

In the illustrated embodiment, the envelope signal is also provided to the bias circuit 13, which controls a bias signal of the power amplifier 3. Thus, the bias signal of the power amplifier 3 changes based on the envelope signal, in this example. Although the envelope signal is provided by the reconstruction filter 25 to the bias circuit 13 in FIG. 4, other implementations are possible. For example, a digital indication of the envelope signal can be provided to the bias circuit 13. As shown in FIG. 4, the power amplifier 3 is powered by the supply voltage V_{PA} and biased by the bias signal.

The directional coupler 4 is positioned between the output of the power amplifier 3 and the input of the duplexing and switching circuit 5, thereby allowing a measurement of output power of the power amplifier 3 that does not include insertion loss of the duplexing and switching circuit 5. The sensed output signal from the directional coupler 4 is provided to the observation receiver 11, which can include mixers for down converting I and Q signal components of the sensed output signal, and DACs for generating I and Q observation signals from the downconverted signals.

The intermodulation detection circuit 12 determines an intermodulation product between the I and Q observation signals and the I and Q signals from the baseband processor 7. Additionally, the intermodulation detection circuit 12 controls the DPD provided by the DPD circuit 9 and/or a delay of the signal delay circuit 8 to control relative alignment between the envelope signal and the RF signal RF_{IN}.

By including a feedback path from the output of the power amplifier 3 and baseband, the I and Q signals can be dynamically adjusted to optimize the operation of the transmit system 30. For example, configuring the transmit system 30 in this manner can aid in providing power control, compensating for transmitter impairments, and/or in performing DPD.

Although illustrated as a single stage, the power amplifier 3 can include one or more stages. Furthermore, RF communication systems such as mobile devices or base stations can include multiple power amplifiers. In such implementations, separate envelope trackers can be provided for different power amplifiers and/or one or more shared envelope trackers can be used.

Modern communication systems (for example, 5G) routinely use complex modulation techniques that result in peak to average power ratio (PAPR) signals of 9 dB or higher. These types of signals present a difficult efficiency challenge for the output power amplifier. One of the simplest types of RF amplifier is a class AB type amplifier. Such an amplifier is relatively straightforward to design and manufacture and can provide peak drain efficiencies of around 65% when operating in the 2 GHz region. However, a problem with this type of amplifier is that when the RF output signal level is reduced, the output voltage swing also reduces and efficiency drops away with the square root of the output power. Accordingly, at a quarter of the output power (−6 dB), the efficiency drops to around half of the peak, about 32% in this example.

Thus, operating at 6 dB back-off or more with a class AB amplifier results in a significant reduction in efficiency because the signal is, on average, being amplified by the amplifier at an inefficient operating point.

Doherty amplifiers have seen a strong resurgence in modern W-CDMA and LTE systems. A 2-way Doherty amplifier provides an improvement over a class AB amplifier, but with higher levels of peak to average ratio being used, it is necessary to improve efficiency at back-off levels of 10 dB and higher. A standard 3-way Doherty amplifier produces peaks in efficiency at 9.5 dB, 4.4 dB and 0 dB, which may be a good fit for LTE transmitters, but requires for each of the two auxiliary amplifiers to be provided with twice the amplifier size/area as compared with the main amplifier.

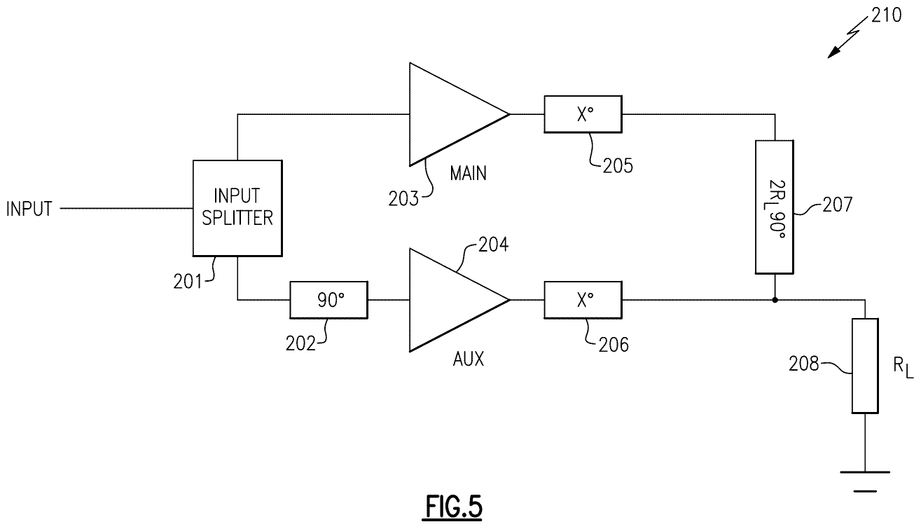

FIG. 5 illustrates an example of a 2-way Doherty power amplifier 210. The 2-way Doherty power amplifier 210 includes an input splitter 201, a 90° input phase shifting component 202, a main amplifier 203, an auxiliary amplifier 204, a first X° output phase shifting component 205, a second X° output phase shifting component 206, an impedance inverter 207 (2R_{L} 90°), and a load 208 (with impedance R_{L}).

The 2-way Doherty amplifier 210 works by partitioning a class AB amplifier into two equally sized amplifiers 203/204 of half the size (of a single-ended class AB amplifier with the same peak power capability). When the output signal level is low, only the main amplifier 203 is active. With increasing output levels the auxiliary amplifier 204 is progressively introduced up to the point in which full power is achieved when both main and auxiliary amplifiers 203/204 are contributing equally to deliver full power.

The 2-way Doherty amplifier 210 is configured with the main amplifier 203 biased in class AB and the auxiliary amplifier 204 biased in class C. This biasing scheme means that at low input drive levels, the main amplifier 203 conducts and the auxiliary amplifier 204 is in an off state. As input levels are increased, the main amplifier 203 drive level also increases and when the output power is about a quarter (−6 dB) of the amplifier maximum, the auxiliary amplifier 204 starts to conduct current.

At low signal levels when the auxiliary amplifier 204 is not active, and the main amplifier 203 is provided with a load of about 100Ω, under the assumption that R_{L}=25Ω. The auxiliary amplifier 204 reaches full voltage swing at about half power. Additionally, full voltage swing means that the main amplifier 203 provides maximum efficiency at about half output power. At this point, the 2-way Doherty amplifier 210 delivers about a quarter (−6 dB) of its peak power capability with maximum efficiency.

As input drive level is increased from the 6 dB back off point, the current contribution into the load from the auxiliary amplifier 204 increases. The increased current being injected results in the impedance looking into the load 208 increasing. The 50Ω impedance inverter 207 between the load 208 and the main amplifier 203 ensures the load of the main amplifier 203 reduces as the current contribution from the auxiliary amplifier 204 increases.

In this regime, as output power increases, there are two processes taking place. The first is that due to the load modulation from the auxiliary amplifier 204, the main amplifier 203 is effectively increasing in size, that is, its capability to produce power is increasing, but it is constantly running at maximum voltage swing and hence maximum efficiency. The other process that is taking place is that both the main amplifier 203 and the auxiliary amplifier 204 are contributing to the total output power.

As drive level increases, these processes continue up until the auxiliary amplifier 204 is at maximum output power (if the transistors of the main amplifier 203 and the auxiliary amplifier 204 are of equal size) and the currents into the load 208 from the main amplifier 203 and the auxiliary amplifier 204 are equal. At this point the main amplifier 203 and the auxiliary amplifier 204 are both presented with about 50Ω of impedance.

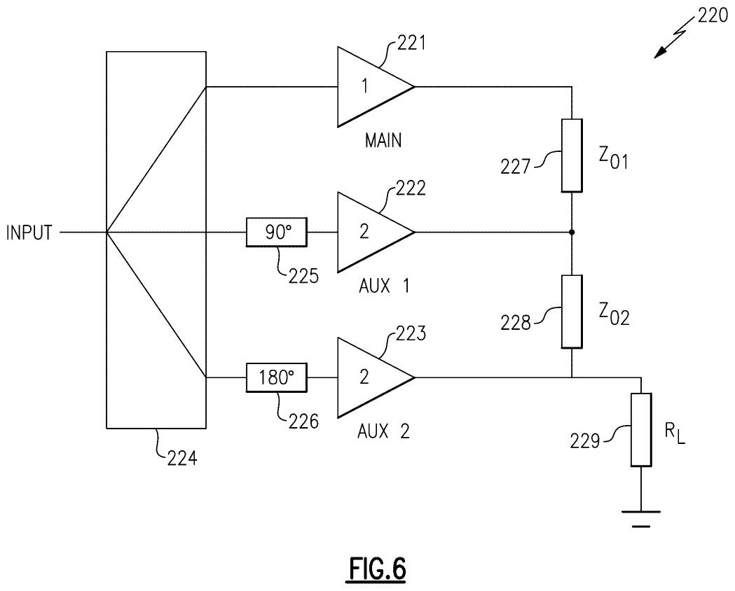

FIG. 6 illustrates an example of a 3-way Doherty power amplifier 220. The 3-way Doherty power amplifier 220 includes a main amplifier 221, a first auxiliary amplifier 222, a second auxiliary amplifier 223, an input splitter 224, a 90° input phase shifting component 225, a 180° input phase shifting component 226, a first impedance 227 (Z₀₁), a first impedance 228 (Z₀₂), and a load 229 (with impedance R_{L}).

The 3-way Doherty power amplifier 220 is a direct extension of the 2-way Doherty power amplifier 210 of FIG. 5. As shown in FIG. 6, the 3-way Doherty power amplifier 220 includes the first auxiliary amplifier 222 and the second auxiliary amplifier 223 each of about twice the size as the main amplifier 221. The first auxiliary amplifier 222 operates with a 90 degree signal lag relative to the main amplifier 221, while the second auxiliary amplifier 223 operates with a 180 degree signal lag relative to the main amplifier 221.

By adjusting the relative device periphery between the main and auxiliary amplifiers, it is possible to achieve a variety of different positions for the efficiency peaks. For example, a designer may be concerned with signals with around 10 dB of PAR. The relative levels of device periphery to achieve an efficiency peak at −9.5 dB, −4.4 dB and 0 dB for the 3-way Doherty power amplifier 220 is 1:2:2 where the first digit is the main amplifier size followed by the first auxiliary amplifier size and thereafter the second auxiliary amplifier size. For this configuration, Z₀₁ is required to be about 70.7Ω, Z₀₂=about 33.3Ω and R_{L}=about 20Ω. At the first efficiency peak the main amplifier 221 will see an impedance of about 90 Ω. In order to match the output to 50 Ω an impedance inverter of value about \sqrt{31.6} Ω is required.

In essence, the 3-way Doherty power amplifier 220 behaves as a 2-way Doherty power amplifier up to the second peak (−4.4 dB) in efficiency and then from the second peak to full power the main amplifier 221 and the first auxiliary amplifier 222 are behaving like a main amplifier which is being load modulated by the current contribution from the second auxiliary amplifier 223.

However, there are two main drawbacks of the 3-way Doherty power amplifier 220. The first is that different device sizes are required to provide efficiency peaks in the 10 dB back off region, which leads to added complexity. The second is that the load modulation of the main amplifier 221 stops in-between the second and third efficiency peaks. This means that the main amplifier 221 is driven into extreme saturation over the last 6 dB of output power.

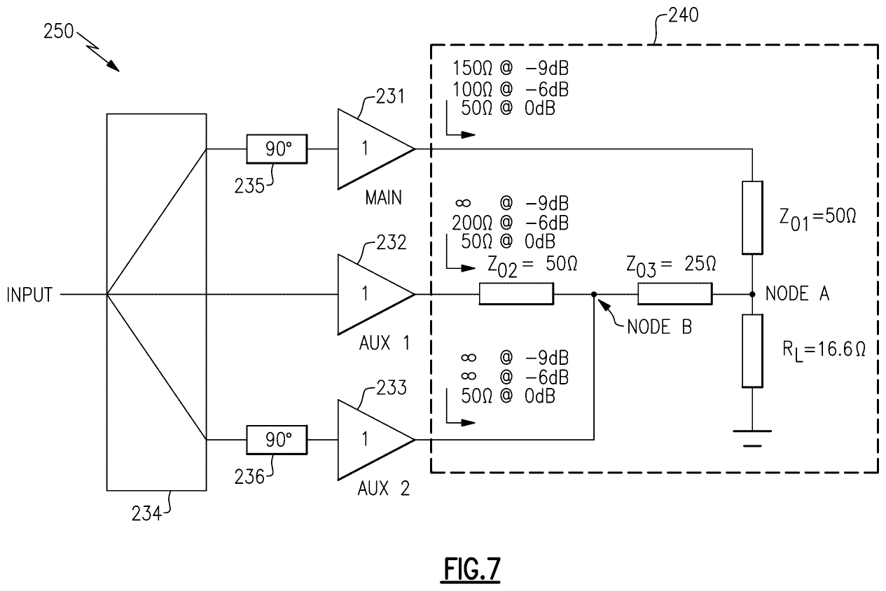

FIG. 7 illustrates one embodiment of a 3-way Doherty power amplifier 250.

The 3-way Doherty power amplifier 250 of FIG. 7 includes an input splitting circuit or splitter 234 (receiving an RF input signal), a main amplifier 231, a first auxiliary amplifier 232, a second auxiliary amplifier 233, and an output combining circuit 240 that includes a first impedance Z₀₁, a second impedance Z₀₂, and a third impedance Z₀₃. The output combining circuit 240 combines the amplifier outputs to generate a combined signal at a node A that is connected to a load impedance R_{L}.

As shown in FIG. 7, the first impedance Z₀₁ is connected between the output of the main amplifier 231 and the node A, the second impedance Z₀₂ is connected between the output of the first auxiliary amplifier 232 and a node B, while the third impedance Z₀₃ is connected between the node B and the node A. The output of the second auxiliary amplifier 233 drives the node B.

Example impedance values for the output combiner 240 are annotated in FIG. 7.

The main amplifier 231, the first auxiliary amplifier 232, and the second auxiliary amplifier 233 have about equal size (for example, matching amplification transistor dimensions within about 10%). The main amplifier 231 and the second auxiliary amplifier 233 each operate with about a 90 degree signal lag relative to the first auxiliary amplifier 232.

The 3-way Doherty power amplifier 250 of FIG. 7 achieves similar performance to the 3-way Doherty power amplifier 230 of FIG. 6 but without having to accommodate output transistors of different sizes. Using transistors of equal sizes for the main and auxiliary stages has a number of practical benefits, including the use of a single (for example, unit cell) RF design.

For example the basic amplifier unit cell for the main and auxiliary amplifiers can be of the same (or very similar) design, thereby reducing development time. Also, having three of the same parts rather than two different parts on the bill of materials leads to scaling economic effects which is important for what are likely to be the most expensive components of the Doherty power amplifier. The configuration also leads to proper load modulation of the main amplifier 231 whose load impedance steadily reduces as drive level is increased, as explained in detail further below.

Doherty Power Amplifier Systems with Envelope Controlled State

Doherty power amplifier systems with envelope controlled state are provided herein. In certain embodiments, a Doherty power amplifier system includes a main amplifier, a first auxiliary amplifier, and a second auxiliary amplifier that operate in combination with one another to amplify an RF signal. The Doherty power amplifier system further includes a bias circuit that biases the first and second auxiliary amplifiers based on an envelope of the RF signal to control a state of the Doherty power amplifier system. For example, in certain implementations, the first and second auxiliary amplifiers are selectively activated based on a power level indicating by the envelope.

Such Doherty power amplifier systems can have high efficiency for high peak to average power ratio (PAPR) waveforms, such as those used in 5G. Furthermore, when using a 3-way Doherty power amplifier and controlling the amplifier's bias based on the envelope of the RF signal, a high efficiency system comparable to envelope tracking (ET) or multi-level supply (MLS) can be realized.

In certain implementations, a load line of the Doherty power amplifier system is modulated to provide high efficiency near the average waveform and allowing peaks up to 10 dB higher power to be transmitted linearly. Compared to a method of using varactors to control the load line, such an approach overcomes the difficulty of having the RF phase vary when the load line is changed. For example, varactors may encounter problems of RF phase changes as more capacitance is added, operate with high voltage supplies, behave non-linearly, and/or suffer from limited range.

Furthermore, when compared to a variable power supply solution, like MLS or ET, the Doherty power amplifier systems herein offer reduced complexity and costs. Moreover, only a small bias control circuit is needed, which can be easily integrated with the amplifiers and/or provides a much simpler implementation than an ET or multi-level power supply scheme.

For very high frequency bandwidth (BW) waveforms larger than 100 MHz a two-way Doherty power amplifier is difficult to control as the bias in each branch needs to follow the modulation in a non-linear function, and encounters delays that are also non-linear.

In certain implementation, the bias control circuit digitally controls the bias of the first and second auxiliary amplifiers based on the envelope signal. For example, when the envelope signal indicates the signal power is less than a first threshold, the bias circuit can turn off both the first and second auxiliary amplifiers such that the RF signal is amplified by the main amplifier but not by the auxiliary amplifiers. Additionally, when the envelope signal indicates the signal power is greater than or equal to the first threshold but less than a second threshold, the bias circuit can turn on the first auxiliary amplifier and turn off the second auxiliary amplifier such that the RF signal is amplified by the first auxiliary amplifier and the main amplifier. Furthermore, when the envelope signal indicates the signal power is greater than or equal to the second threshold, the bias circuit can turn on both the first auxiliary amplifier and the second auxiliary amplifier such that the RF signal is amplified by the first auxiliary amplifier, the second auxiliary amplifier, and the main amplifier.

By using a digital control for enabling the bias of each amplifier branch and using the envelope signal to limit the BW of bias changes to a BW lower than the RF signal BW, more predictable, time advanced and/or less critical bias changes can be used, resulting in better fidelity throughout the system. Due to its slow changing rate, the bias change can be more predictable. Moreover, it may only depend on larger, well defined components like resistors and capacitors. Using a time advanced envelope signal for the bias changes allows the system to be in a state where it is linear with respect to the fast RF power changes, rather than having to follow the rapidly changing RF with a response in bias.

In contrast, a 3-way Doherty without time advanced state control (self-biased) has limited BW due to the limitations of fast varying bias required to track the RF at the modulation rate, and the bias of the auxiliary power amplifiers is very non-linear. In addition, a power amplifier in ET mode with tracker using a variable voltage supply (for example, 3 or more levels of voltage for MLS or ET) necessitates a supply voltage filter with inductor and capacitor components that that carry the full current and serve to linearize supply voltage transitions.

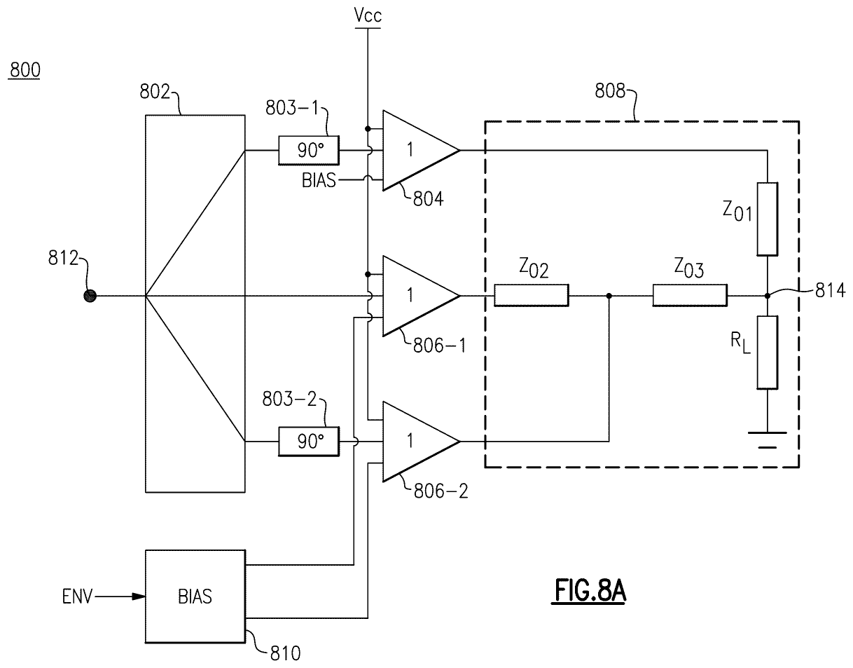

FIG. 8A is a schematic diagram of one embodiment of a Doherty power amplifier system 800. The Doherty power amplifier system 800 includes an input splitting circuit 802, a main amplifier 804, a first auxiliary amplifier 806-1, a second auxiliary amplifier 806-2, an output combining circuit 808, and a bias circuit 810. The output combining circuit 808 includes a first impedance Z₀₁, a second impedance Z₀₂, and a third impedance Z₀₃ for connecting to a load impedance R_{L}, as was described earlier with reference to FIG. 7.

In the illustrated embodiment, the Doherty power amplifier system 800 includes two auxiliary amplifiers, but the number of the auxiliary amplifiers included in the Doherty power amplifier system 800 is not limited thereto. For example, in another embodiment, the Doherty power amplifier system 800 includes a main amplifier and three or more auxiliary amplifiers.

The input splitting circuit 802 receives an RF input signal at an input node or terminal 812. The input splitting circuit 802 is configured to split the received RF input signal into a plurality of RF input signals (also referred to herein as portions of or components of the RF input signal).

In the illustrated embodiment, the first RF input signal is provided to the input of the main amplifier 804 with about 90 degrees (for example, 90°+/−9°) of additional phase delay relative to the second RF input signal provided to the input of the first auxiliary amplifier 806-1. Additionally, the third RF input signal is provided to the input of the second auxiliary amplifier 806-2 with about 90 degrees of additional phase delay relative to the second RF input signal provided to the input of the first auxiliary amplifier 806-1. Such phase delay can be provided using explicit phase shifting components 803-1/803-2 or integrated into the input splitting circuit 802.

The main amplifier 804 receives the first RF input signal from a first output of the input splitting circuit 802. Additionally, the main amplifier 804 amplifies the first RF input signal to generate a first RF output signal. The main amplifier 804 is powered by a supply voltage Vcc and biased by a biasing signal BIAS. In certain implementations, the biasing signal BIAS for the main amplifier 804 is also generated by the bias circuit 810. In other implementations, a separate bias circuit is used.

In certain implementations, the main amplifier 804 is activated regardless of the power level of the RF input signal. Accordingly, when the Doherty power amplifier system 800 is enabled (turned on), the biasing signal may remain constant during the operation of the Doherty power amplifier system 800.

The main amplifier 804 can include a bipolar transistor having a collector, a base and an emitter. The supply voltage may be applied to the collector (for example, through an inductor), and the biasing signal may be applied to the base (for example, through an inductor or resistor) of the bipolar transistor. Additionally, the emitter can be grounded. Although one example of an amplifier structure for the main amplifier 804 is described, other implementations are possible. For example, the teachings herein are also applicable to configurations using field-effect transistors (for example, silicon-on-insulator or SOI technologies) and/or to other amplifier topologies, such as cascode amplifier topologies.

The first auxiliary amplifier 806-1 receives the second RF input signal from a second output of the input splitting circuit 802, while the second auxiliary amplifier 806-2 receives the third RF input signal from a third output of the input splitting circuit 802. When activated by the bias circuit 810, the first auxiliary amplifier 806-1 amplifies the second RF input signal to generate a second RF output signal. Additionally, when activated by the bias circuit 810, the second auxiliary amplifier 806-2 amplifies the third RF input signal to generate a third RF output signal.

Accordingly, the first auxiliary amplifier 806-1 amplifies the second RF input signal when powered by the supply voltage Vcc and biased by a first biasing signal provided by the bias circuit 810. Additionally, the second auxiliary amplifier 806-2 amplifies the third RF input signal when powered by the supply voltage Vcc and biased by a second biasing signal provided by the bias circuit 810.

Each of the auxiliary amplifiers can include a bipolar transistor with a collector, a base and an emitter, in some implementations. However, other transistor types, such as SOI FETs, are also possible. In certain implementations, the structure and/or amplifier topology of the first auxiliary amplifier 806-1 and the second auxiliary amplifier 806-2 may be same as that of main amplifier 804. In the illustrated embodiment, the transistor size of each auxiliary amplifier is about equal to that of the main amplifier 804.

The supply voltage Vcc can be fixed in certain embodiments. In another embodiment, the supply voltage Vcc can be fixed over a transmit slot or frame of the RF input signal, but can be adapted or adjusted between transmissions. Thus, operation of the Doherty power amplifier system 800 does not require that the voltage level of the supply voltage Vcc be dynamically adjusted (for instance, using envelope tracking or MLS modulation) over time during a transmit slot.

In certain implementations, the supply voltage Vcc applied to the auxiliary amplifiers remains constant even when one or more of the auxiliary amplifiers are controlled to be turned off. In other words, the activation of the auxiliary amplifier(s) is controlled by the respective biasing signals from the bias circuit 810 while the supply voltage Vcc remains constant.

As shown in FIG. 8A, the bias circuit 810 receives an envelope signal ENV, which can be in a wide variety of signals types or formats. The envelope signal ENV indicates a signal power level of the RF input signal. The bias circuit 810 processes the envelope signal ENV to set bias signal levels for the first biasing signal that biases the first auxiliary amplifier 806-1 and for the second biasing signal that biases the second auxiliary amplifier 806-2.

In certain embodiments, when the envelope signal ENV indicates the signal power is less than a first threshold, the bias circuit 810 turns off both the first auxiliary amplifier 806-1 and the second auxiliary amplifier 806-2 such that the RF input signal is amplified by the main amplifier 804 but not by the auxiliary amplifiers. Additionally, when the envelope signal ENV indicates the signal power is greater than or equal to the first threshold but less than a second threshold, the bias circuit 810 can turn on the first auxiliary amplifier 806-1 and turn off the second auxiliary amplifier 806-2 such that the RF input signal is amplified by the first auxiliary amplifier 806-1 and the main amplifier 804. Furthermore, when the envelope signal ENV indicates the signal power is greater than or equal to the second threshold, the bias circuit 810 can turn on both the first auxiliary amplifier 806-1 and the second auxiliary amplifier 806-2 such that the RF input signal is amplified by the first auxiliary amplifier 806-1, the second auxiliary amplifier 806-2, and the main amplifier 804.

For example, Table 1 below depicts example operation of the Doherty power amplifier system 800 for the case in which the first threshold is −9 dB back off power and the second threshold is −6 dB back off power. Although example thresholds are depicted, other thresholds can be used.

TABLE 1

| | Main | First Auxiliary | Second Auxiliary |
|---|---|---|---|
| State | Amplifier | Amplifier | Amplifier |
| <−9 dB | ON | OFF | OFF |
| >−9 dB | ON | ON | OFF |
| but <−6 dB | | | |
| >−6 dB | ON | ON | ON |

In the example above, the first auxiliary amplifier 806-1 is either turned on by setting the first biasing signal to an active level to turn on the first auxiliary amplifier 806-1, or turned off by setting the first biasing signal to a disabled level. Likewise, the second auxiliary amplifier 806-2 is either turned on by setting the second biasing signal to the active level (which can be the same or different from the active level of the first biasing signal) to turn on the second auxiliary amplifier 806-2, or turned off by setting the second biasing signal to the disabled level (which can be the same or different from the disabled level of the first biasing signal).

Accordingly, in this example, the Doherty power amplifier system 800 is configured to have three states of operation. In the first state, both the first auxiliary amplifier 806-1 and the second auxiliary amplifier 806-2 are turned off. More specifically, in the first state, only the main amplifier 806 is activated since the signal power of the RF input signal does not exceed the first threshold. In the second state, the first auxiliary amplifier 806-1 is turned on and the second auxiliary amplifier 806-2 is turned off. In the second state, the signal power of the RF input signal exceeds the first threshold but does not exceed the second threshold, and the main amplifier 804 and the first auxiliary amplifier 806-1 are activated. In the third state, both the first auxiliary amplifier 806-1 and the second auxiliary amplifier 806-2 are turned on. In the third state, the signal power of the RF input signal exceeds the second threshold, and the main amplifier 804, the first auxiliary amplifier 806-1 and the second auxiliary amplifier 806-2 are turned on.

Since each auxiliary amplifier is either turned on or off by the respective biasing signals, such biasing control is referred to a digital control. By using digital control for enabling the bias of each branch, more predictable, time advanced and/or less critical bias changes can be used, resulting in better fidelity throughout the Doherty power amplifier system 800. Moreover, changing the state of the Doherty power amplifier system 800 based on the envelope signal ENV provides better performance relative to implementations in which the Doherty power amplifier system 800 is self-biased by the RF input signal.

With continuing reference to FIG. 8A, the output combining circuit 808 combines the first RF output signal from the main amplifier 804 with the second RF output signal from the first auxiliary amplifier 806-1 and the third RF output signal from the second auxiliary amplifier 806-2. The combined RF output signal is provided to the output node or terminal 814. In certain implementations, the output terminal 814 is connected to an antenna through one or more components, such as switches, multiplexers, and/or other antenna access control components. The load impedance R_{L} can represent the load presented by such components.

The bias circuit 810 may generate the respective biasing signal based on an envelope signal ENV that serves as a bias control signal. Thus, the bias circuit 810 generates biasing signals based on the envelope of the RF input signal. The envelope signal ENV can be generated at baseband (for example, provided as an output of a transceiver). In certain implementations, the envelope signal ENV is generated as part of digital pre-distortion (DPD) applied to the RF input signal.

The envelope signal ENV can be time-advanced (early) with respect to the RF input signal in some implementations, thereby aiding to synchronize biasing of the Doherty power amplifier system 800 with proper amplification of the RF input signal. Such a configuration provides superior performance relative to a Doherty power amplifier that is self-biased based on the RF input signal alone.

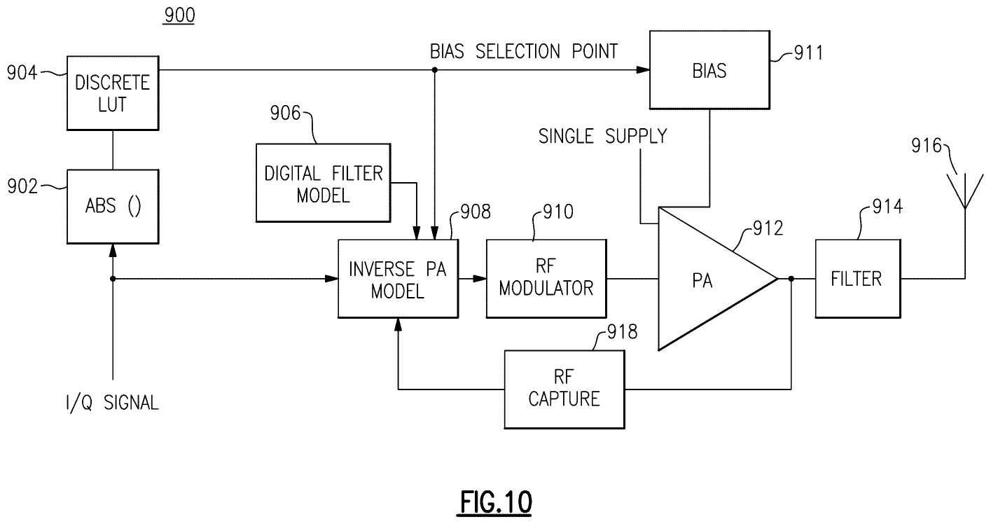

In case the wireless communication device comprises a plurality of Doherty power amplifiers, each of the Doherty power amplifiers may be controlled independently of each other. For example, the embodiment of FIG. 11 depicts one example of such a configuration.

According to embodiments of the present disclosure, the control occurs on the base (low current) side of the transistor, enabling an up to hundred-fold lower control current than on the collector. Or in the case of SOI FET, at the gate side of the transistor. In turn, this permits very fast switching or accurate slow switching with good impedance control without significant power loss. Another advantage is that the bias of each amplifier is controlled at a slow rate, and adjustments may be made at the same slow rate to compensate for mismatch.

The Doherty power amplifier system 800 can be implemented with input splitting, output splitting, and/or amplifier sizing in a wide variety of ways. In one example, an output combining impedances equal to or similar to that shown in FIG. 7 is used. However, other impedance values are possible.

FIG. 8B is a schematic diagram of one embodiment of a Doherty power amplifier system 800′. The Doherty power amplifier system 800′ includes an input splitting circuit 802, a main amplifier 804, a first auxiliary amplifier 806-1, a second auxiliary amplifier 806-2, an output combining circuit 808, and a bias circuit 810′.

The Doherty power amplifier system 800′ of FIG. 8B is similar to the Doherty power amplifier system 800 of FIG. 8A, except that the Doherty power amplifier system 800′ of FIG. 8B includes the bias circuit 810′ which operates on an analog differential envelope signal V_{ET}±/V_{ET}. The Doherty power amplifier systems herein can receive envelope signals of a wide variety of signal types and formats, including both digital and analog formats.

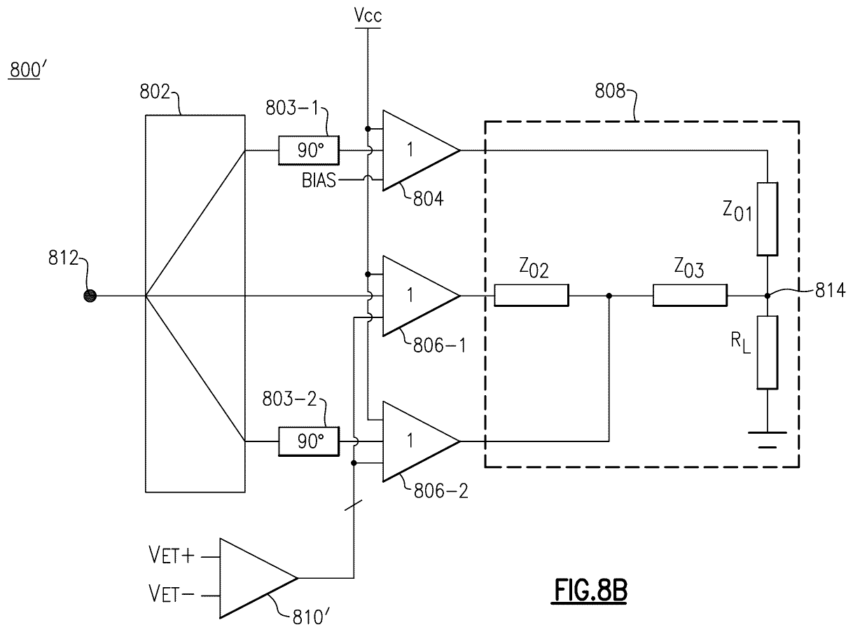

FIG. 9 illustrates an example of experimental data representing improved efficiency for one implementation of the Doherty power amplifier system 800 of FIG. 8A. Plots of gain versus output power, power added efficiency (PAE) versus output power, amplitude distortion (AM/AM) versus output power, and phase distortion (AM/PM) versus output power are depicted. As shown in FIG. 9, system efficiency of 40% for 10 dB back-off is comparable in performance to envelope tracking power amplifiers, anticipating good realizable performance.

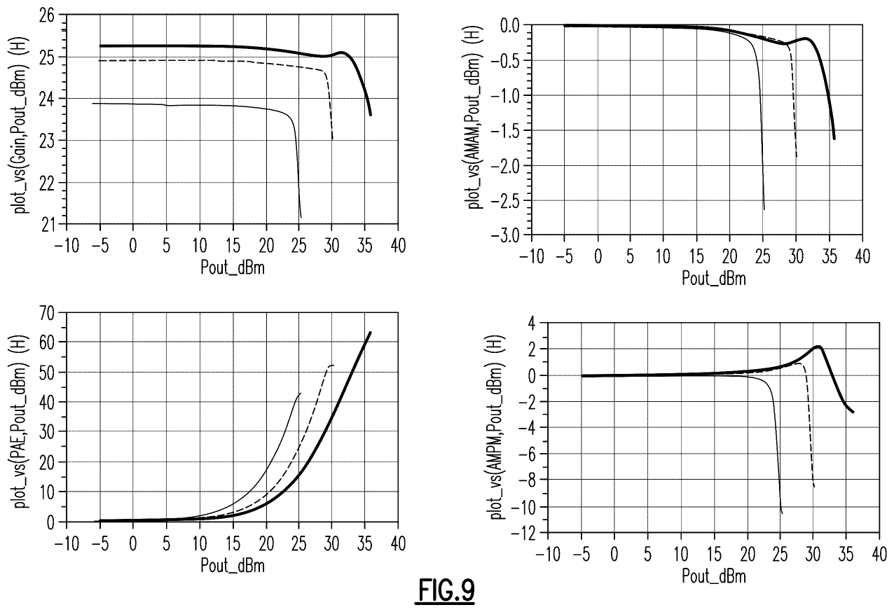

FIG. 10 is a schematic diagram of one embodiment of a transmit system 900 for a mobile device, base station, or other RF communication system. The transmit system 900 includes an absolute value block 902 (receiving digital in-phase/quadrature-phase or I/Q data), a discrete look-up table (LUT) 904, a digital filter model 906 (modeling a Vcc filter), an inverse power amplifier model 908 (receiving the digital I/Q data), an RF modulator 910, a bias circuit 911, a Doherty power amplifier 912, a filter 914, an antenna 916, and an RF capture circuit 918.

As shown in FIG. 10, samples of the RF output signal of the Doherty power amplifier 912 captured by the RF capture circuit 918 can be fed back to the inverse power amplifier model 908 in order to shape the RF input signal. By shaping the RF input signal using the inverse power amplifier model 908, the linearity of the RF output signal can be improved. For example, the inverse power amplifier model 908 can perform DPD to provide a linearity enhancement.

The inverse PA model 908 receives the I/Q data and an output signal from a digital filter module 906. The RF modulator 910 is connected between the inverse PA model 908 and the Doherty power amplifier 912, and is configured to generate the RF signal based on digital shaped baseband data provided from the inverse PA model 908.

The Doherty power amplifier 912 can be implemented in accordance with any of the embodiments herein. In certain implementations, the biasing of the Doherty power amplifier 912 by the bias circuit 911 is based on envelope data of the RF input signal, which in certain implementations is provided by the output of the discrete LUT 904. Such envelope data can also be used to control DPD provided by the inverse PA model 908.

According to an embodiment of the present disclosure, the envelope signal used for selecting bias settings of a Doherty power amplifier can also be used by circuitry providing DPD to an RF input signal amplified by the Doherty power amplifier.

The transmit system 1000 of FIG. 10 can implement the Doherty power amplifier schemes herein using the same DPD as an MLS envelope tracking system and using the same digital interface as an MLS envelope tracking system.

Accordingly, the Doherty power amplifier systems herein can be compatible with existing baseband/transceiver technologies used for envelope tracking systems, thus facilitating ease of implementation.

FIG. 11 is a schematic diagram of another embodiment of a transmit system 1100 for a mobile device, a base station, or other RF communication system.

The transmit system 1100 includes a first Doherty power amplifier system 1102, a second Doherty power amplifier system 1104, and a third Doherty power amplifier system 1106 each implemented in accordance with the Doherty power amplifier system 800′ of FIG. 8B. The transmit system 1100 further includes a transceiver 1108 that generates RF input signals for each of the Doherty power amplifiers, as well as envelope signals for controlling biasing of each of the Doherty power amplifiers. The transmit system 1100 further includes a boost converter 1110 that controls a common power supply voltage provided to each Doherty power amplifier.

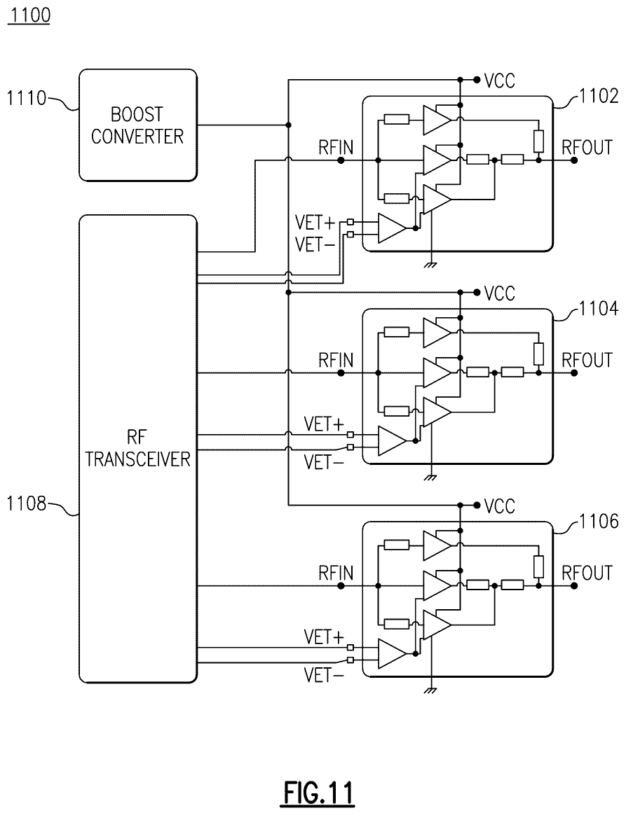

FIG. 12 is a schematic diagram of one embodiment of an envelope tracking transmit system 1200 for a mobile device, a base station, or other RF communication system. The envelope tracking transmit system 1200 includes an absolute value block 1202, a discrete LUT 1204, a digital filter model 1206, an inverse power amplifier model 1208, an RF modulator 1210, a bias circuit 1211, a power amplifier 1212, a filter 1214, an antenna 1216, an MLS matrix 1218, a filter 1220, a linear amplifier 1222, and a supply voltage filter 1224 (which includes a series supply voltage inductor and a shunt capacitor).

In FIG. 12, envelope data provided as an output of the discrete LUT 1204 serves multiple functions, including controlling the power supply voltage of the power amplifier 1212, controlling a bias of the power amplifier 1212, and/or controlling DPD of an RF input signal to the power amplifier 1212.

### Combiners for Doherty Power Amplifier Systems

In certain embodiments, combiners for Doherty power amplifier systems are provided. The combiner structure can include a first balun combiner for combining an output of a first auxiliary amplifier and a second auxiliary amplifier, and a second balun combiner for combining the output of a main amplifier and an output of the first balun combiner. Each combiner can include a balun having a first conductor (also referred to as a primary conductor or winding) connected between a first input port and an output port, a second conductor (also referred to as a secondary conductor or winding) connected between an isolated node and a second input port and magnetically coupled to the first conductor. An isolation capacitor is connected between the first input port and the isolated node, and an output capacitor is connected between the second input port and the output port. In certain implementations, the balun combiner further includes a termination capacitor between the isolated node and ground.

Such a balun combiner can provide asymmetric performance suitable for a 3-way Doherty power amplifier. For example, such combiners can serve as a building block for any of the Doherty power amplifier systems herein.

In certain implementations, the first balun combiner and the second balun combiner have different impedance ratios.

For example, the second balun combiner is well-suited for accommodating a 3:1 impedance ratio, for instance, a 150Ω to 50Ω impedance range (3:1) of the main amplifier of FIG. 7 across −9 dB, −6 dB, and 0 dB states. Thus, the balun combiner can be well-suited for addressing a 150 Ohm load and/or a 9 dB backed off state. In certain implementations, the first balun combiner (for combining the outputs of the auxiliary amplifiers) accommodates a 2:1 impedance ratio, for instance, a 100Ω to 50Ω impedance range (2:1) of the auxiliary amplifiers.

In certain implementations, the first balun combiner and the second balun combiner are passive combiners with no active components, such as transistors or diodes.

The first input port and the second input port operate with phase delayed input signals. In certain implementations, the balun combiner operates as a quadrature combiner operating with 90° phase-shifted signals received at the first input port and the second input port. For example, the signal at the second input port can lag the signal at the first input port by about a quarter wavelength or 90°.

Although described above in the context of an application in which the structure is used as a combiner for a Doherty power amplifier, the structures herein can also operate as a splitter when the output port is driven with an RF input signal and split signals are outputted from the first input port and the second input port. Thus, although described in several embodiments in the context of a combiner, the balun-type splitting/combining structures herein can be generically described as having a first port (corresponding to the first input port when used as a combiner and to a first output power when used as a splitter), a second port (corresponding to the second input port when used as a combiner and to a second output port when used as a splitter), and a third port (corresponding to the output port when used as a combiner and to an input port when used as a splitter).

In certain implementations, the balun combiner further includes a third conductor (also referred to as a second secondary conductor or winding) connected in parallel with the second conductor. The second conductor and the third conductor are each magnetically coupled to the first conductor of the balun, but in certain implementations with opposite coupling polarity.

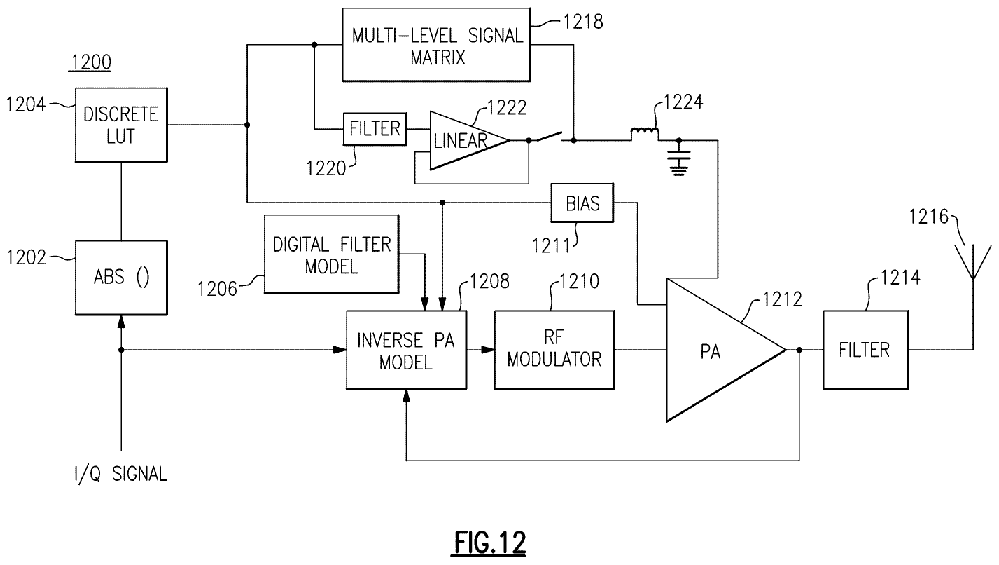

FIG. 13 is a schematic diagram of one embodiment of a balun combiner 400 for a Doherty power amplifier system. A balun combiner, such as the balun combiner 400 of FIG. 13, is also referred to herein as a passive balun-based combiner.

The balun combiner 400 includes a first input port 431 which can be configured to receive a carrier-amplified signal of a Doherty power amplifier, a second input port 432 which can be configured to receive a peaking-amplified signal of a Doherty power amplifier, and an output port 433 which outputs a combination of the signals received at the first input port 431 and the second input port 432. The main amplifier of a Doherty power amplifier may be also referred to as a carrier amplifier (or carrier stage), and the auxiliary amplifier may be referred to as a peaking amplifier (or peak stage).

When used to combine the outputs of two auxiliary or peaking amplifiers, the first input port 431 can be configured to receive a first peaking-amplified signal and the second input port 432 can be configured to receive a second peaking-amplified signal.

The balun combiner 400 includes a transformer (e.g., a balun transformer or balun) 410 having a first coil 401 (also referred to as a first or primary winding or conductor) and a second coil 402 (also referred to as a second or secondary winding or conductor).

The first coil 401 is connected between a first port 411 and a second port 412 of the balun 400, while the second coil 402 is connected between a third port 413 and a fourth port 414 of the balun 400. The first port 411 and the third port 413 are coupled by a first (or isolation) capacitor 421 and the second port 412 and the fourth port 414 are coupled by a second (or output) output capacitor 422. The third port 413 is coupled to ground via a termination circuit which, in FIG. 11, includes a third (or termination) capacitor 423.

In some implementations, the capacitance of the first capacitor 421 and the second capacitor 422 are equal. In some implementations, the capacitance of the third capacitor 423 is twice the capacitance of the first capacitor 421 and/or the second capacitor 422.

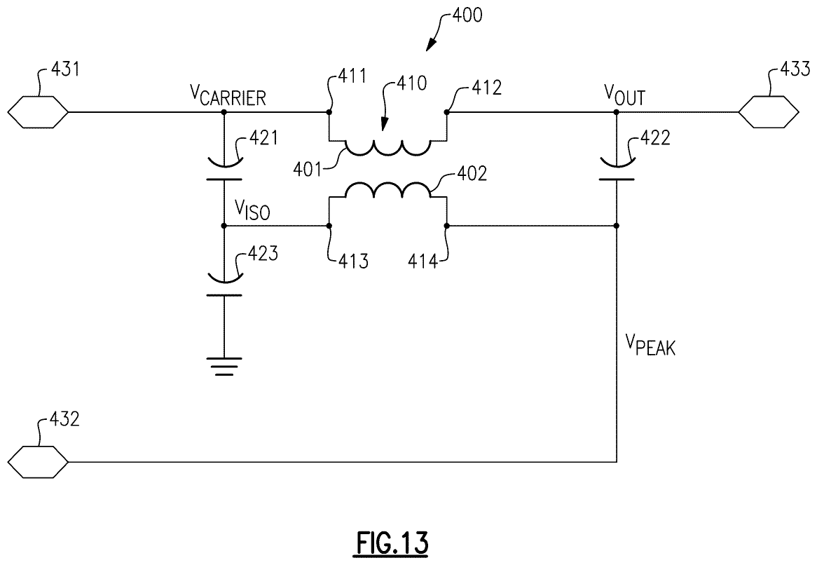

FIG. 14 illustrates impedance trajectories 444 resulting from Doherty action in the balun combiner 400 of FIG. 13. In the Doherty combiner of FIG. 13, values of various performance and operating parameters are examples, and can be adjusted appropriately for different applications.

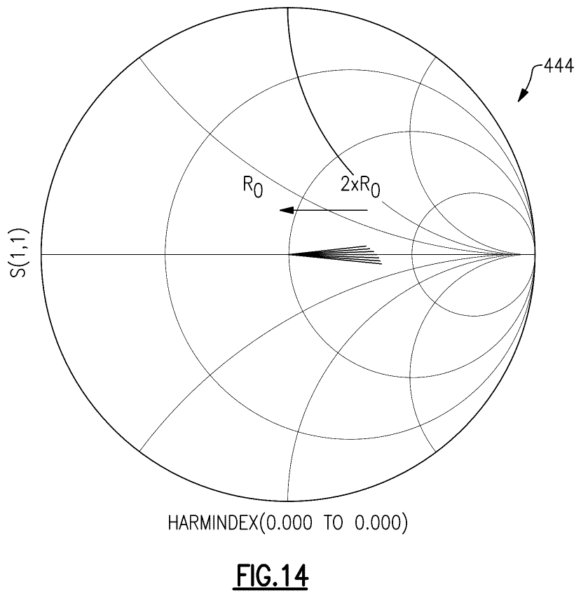

FIG. 15 is a schematic diagram of another embodiment of a balun combiner 500 for a Doherty power amplifier system. The balun combiner 500 may be used as an output combining circuit of a Doherty power amplifier system implemented in accordance with the teachings herein.

The balun combiner 500 includes a balun transformer 510 that includes a first coil 501, a second coil 502, and a third coil 503. Thus, the balun transformer 510 includes the third coil 503 (also referred to as a third conductor or winding) in addition to the coils discussed earlier with respect to the balun transformer 410 illustrated in FIG. 13. The third coil 503 is in parallel to the second coil 502 and is also magnetically coupled to the first coil 501.

The balun combiner 500 includes a first input port 531 which can be configured to receive a carrier-amplified signal of a Doherty PA (main amplifier), a second input port 532 which can be configured to receive a peaking-amplified signal of a Doherty PA (an auxiliary amplifier or combination of two or more auxiliary amplifiers), and an output port 533 which outputs a combination of the signals received at the first input port 531 and the second input port 532.

With continuing reference to FIG. 15, the first coil 501 is arranged between a first port 511 and a second port 512. The first port 511 may be coupled to the first input port 531 which is configured to receive amplified signal from the main amplifier. That is, the first port 511 may be coupled to the main amplifier through the first input port 531. The second port 512 may be coupled to the output port 533. The second coil 502 implemented between a third port 513 and a fourth port 514. The first port 511 and the third port 513 are coupled by a first capacitor 521, and the second port 512 and the fourth port 514 are coupled by a second capacitor 522, respectively. In some implementations, the capacitance of the first capacitor 421 and the second capacitor 522 are equal. In some implementations, the capacitance of the third capacitor 523 is twice the capacitance of the first capacitor 421 and/or the second capacitor 522.

The first coil 501 is magnetically coupled to the second coil 502. The second coil 502 is connected in parallel to the third coil 503. The first coil 501 has an identical direction of windings to the second coil 502. The first and second coils 501, 502 have opposite direction of windings to the third coil 503. Thus, the second coil 502 and the third coil 503 are both coupled to the first coil 501, but with opposite coupling polarity.

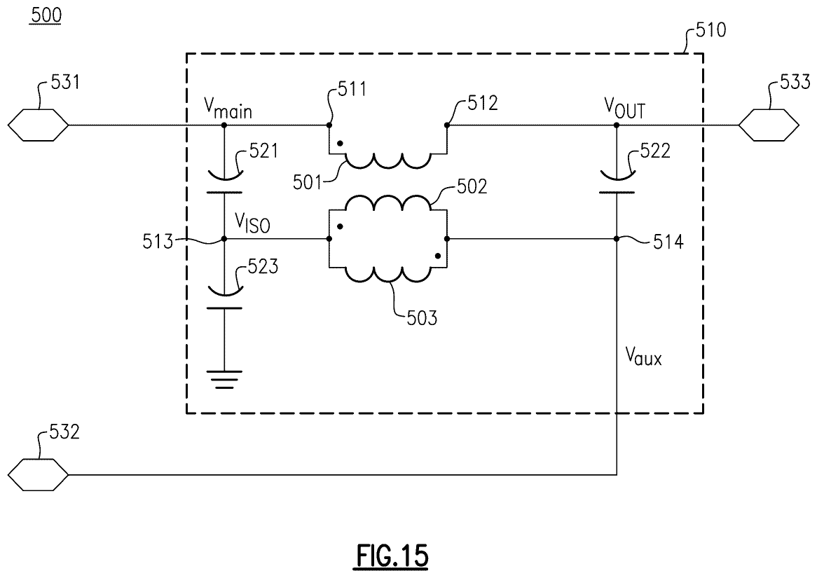

FIG. 16 illustrates impedance trajectories 555 resulting from Doherty action in the balun combiner 500 of FIG. 15. In the Doherty combiner of FIG. 15, values of various performance and operating parameters are examples, and can be adjusted appropriately for different applications.

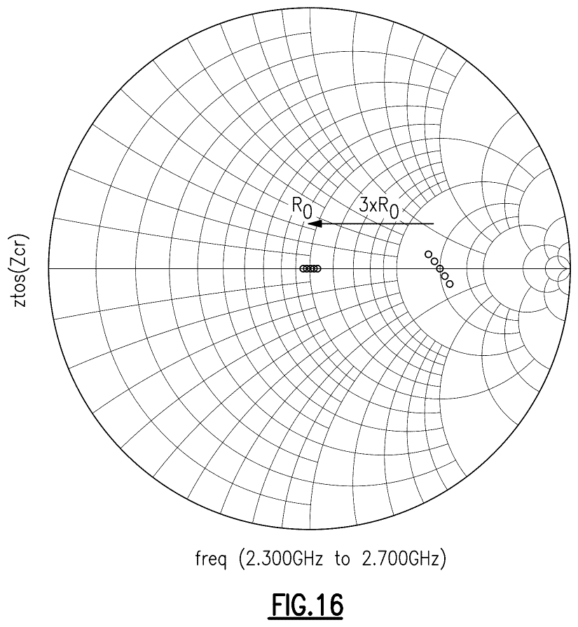

FIG. 17 is an example of an enhanced Doherty combiner configuration 500′ with extended combiner stages according to an embodiment of the present disclosure.

As shown in FIG. 17, the configuration 500′ may be modified to be suitable for 3-way Doherty amplifier. In this embodiment, the configuration 500′ is configured to operate in connection with a main amplifier, a first auxiliary amplifier, and a second auxiliary amplifier. The configuration 500′ may further include a third input port 534 which is configured to receive an amplified signal from the second auxiliary amplifier. The configuration 500′ may further include an additional balun combiner 510′ which is arranged between the first auxiliary amplifier and the second auxiliary amplifier.

The additional balun combiner 510′ may have an identical topology to the balun combiner 510 arranged between the main amplifier and the first auxiliary amplifier, and with component values selected to achieve desired impedance ratios. As shown in FIG. 17, the additional combiner 510′ includes a first coil 501′, a second coil 502′, and a third coil 503′. The first coil 501′ is arranged between a first port 511′ and a second port 512′. The second coil 502′ is arranged between a third port 513′ and a fourth port 514′. The first coil 501′ is magnetically coupled to the second coil 502′. The second coil 502′ is connected in parallel to the third coil 503′. The first coil 501′ has the same direction of windings with respect to the second coil 502′. The first and second coils 501′, 502′ have opposite direction of windings with respect to the third coil 503′.

The balun combiner 510 and the additional balun combiner 510′ may be connected to each other via an offset line 540 included at Vaux. According to an embodiment, the offset line 540 may be arranged between the fourth port 514 of the balun combiner 510 and the second port 512′ of the additional balun combiner 510′.

The values of components included in the balun combiner 510 may be different from those included in the additional combiner 510′. More specifically, the balun combiner 510 may provide an impedance ratio defined based on a number of whole amplifiers, including the main amplifier, the first auxiliary amplifier and the second auxiliary amplifier. For example, the impedance ratio of the balun combiner 510 disposed between the main amplifier and the first auxiliary amplifier may be 3:1. The additional combiner 510′ may provide an impedance ratio defined based on a number of auxiliary amplifiers. In this embodiment, the auxiliary amplifiers may include the first auxiliary amplifier and the second auxiliary amplifier. For example, the impedance ratio of the additional balun transformer 510′ may be 2:1.

Although it has been described that the configuration 500′ includes the first input port 531, second input port 532 and the third input port 534, however, the number of input ports are not limited thereto. For example, depending on the number of amplifiers (main amplifier and auxiliary amplifiers) to which the configuration 500, 500′ can be coupled, the number of input port can be adjusted.

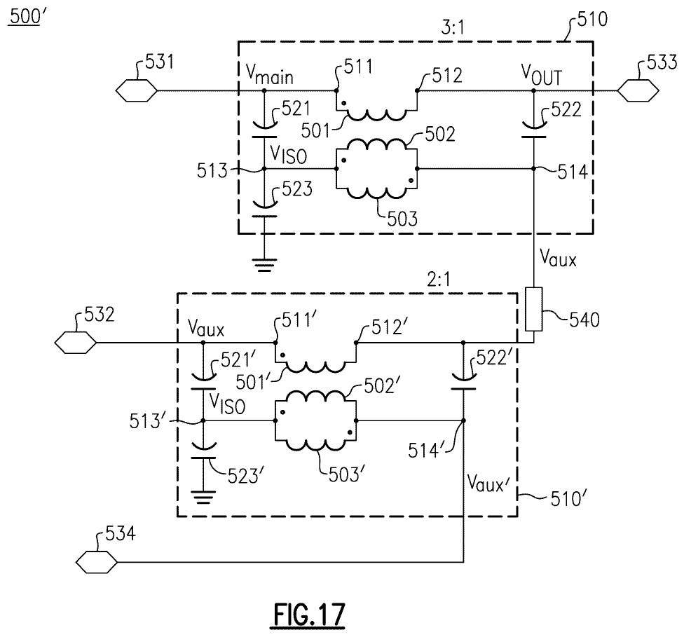

FIG. 18A illustrates the modification of impedance presented to the main amplifier of the configuration 500′ of FIG. 17. As shown in FIG. 18A, the impedance presented to the main amplifier at 0 dB back-off state would be 50 Ohm. In this state, the main amplifier, the first auxiliary amplifier and the second auxiliary amplifier may be activated. In addition, the impedance seen from the main amplifier at 6 dB back-off state would be 100 Ohm. In this state, the main amplifier and the first auxiliary amplifier may be activated, but the second auxiliary amplifier may be turned off. In addition, the impedance seen from the main amplifier at 9 dB back-off state would be 150 Ohm. In this state, only the main amplifier may be activated, but the first and second auxiliary amplifiers may be turned off.

FIG. 18B illustrates the modification of impedance presented to the first auxiliary amplifier of the configuration 500′ of FIG. 17. As shown in FIG. 18A, the impedance presented to the first auxiliary amplifier at 0 dB back-off state would be 50 Ohm. In addition, the impedance seen from the first auxiliary amplifier at 6 dB back-off state would be 200 Ohm.

According to embodiments of the present disclosure, an asymmetric or N-way Doherty power amplifier can be optimized for back-off states (for example, 9 dB) efficiently even for 5G signals of high PAPR.

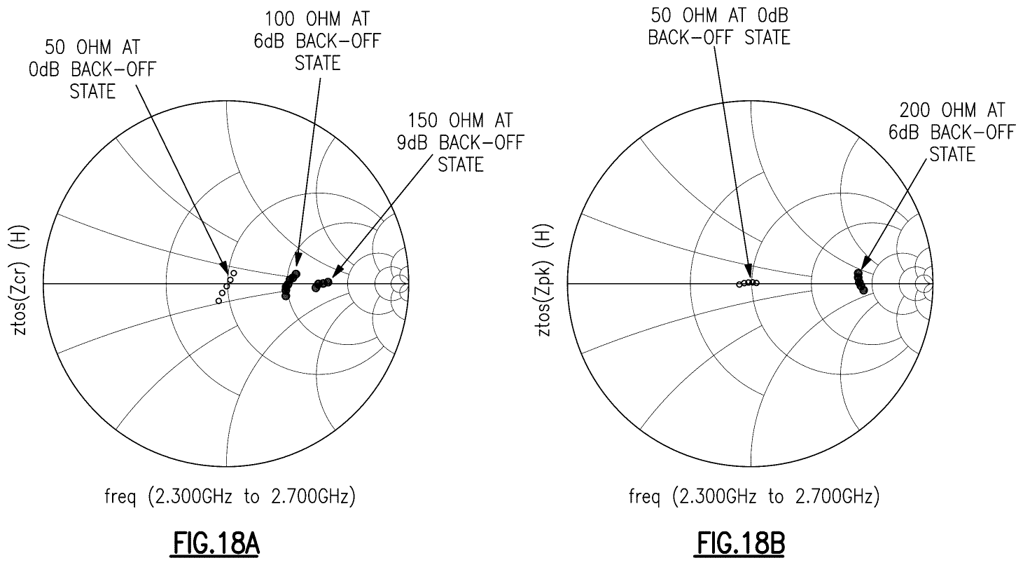

FIG. 19A is a schematic diagram of one embodiment of a packaged module 1900. FIG. 19B is a schematic diagram of a cross-section of the packaged module 1900 of FIG. 19A taken along the lines 19B-19B.

The packaged module 1900 includes an IC or die 1901, surface mount components 1903, wirebonds 1908, a package substrate 1920, and encapsulation structure 1940. The package substrate 1920 includes pads 1906 formed from conductors disposed therein. Additionally, the die 1901 includes pads 1904, and the wirebonds 1908 have been used to electrically connect the pads 1904 of the die 1901 to the pads 1906 of the package substrate 1920.

The die 1901 includes a power amplifier 1946, which can be implemented in accordance with any of the embodiments herein.

The packaging substrate 1920 can be configured to receive a plurality of components such as the die 1901 and the surface mount components 1903, which can include, for example, surface mount capacitors and/or inductors.

As shown in FIG. 19B, the packaged module 1900 is shown to include a plurality of contact pads 1932 disposed on the side of the packaged module 1900 opposite the side used to mount the die 1901. Configuring the packaged module 1900 in this manner can aid in connecting the packaged module 1900 to a circuit board such as a phone board of a wireless device. The example contact pads 1932 can be configured to provide RF signals, bias signals, power low voltage(s) and/or power high voltage(s) to the die 1901 and/or the surface mount components 1903. As shown in FIG. 19B, the electrically connections between the contact pads 1932 and the die 1901 can be facilitated by connections 1933 through the package substrate 1920. The connections 1933 can represent electrical paths formed through the package substrate 1920, such as connections associated with vias and conductors of a multilayer laminated package substrate.

In some embodiments, the packaged module 1900 can also include one or more packaging structures to, for example, provide protection and/or facilitate handling of the packaged module 1900. Such a packaging structure can include overmold or encapsulation structure 1940 formed over the packaging substrate 1920 and the components and die(s) disposed thereon.

It will be understood that although the packaged module 1900 is described in the context of electrical connections based on wirebonds, one or more features of the present disclosure can also be implemented in other packaging configurations, including, for example, flip-chip configurations.

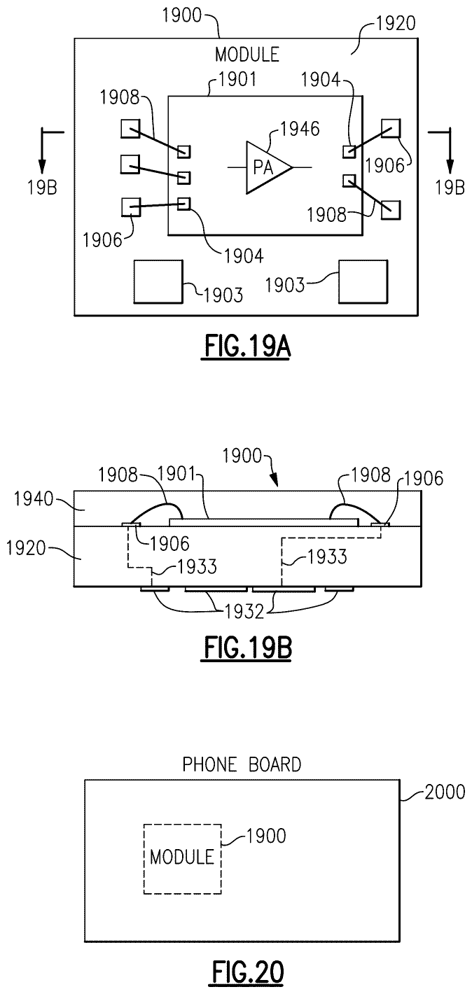

FIG. 20 is a schematic diagram of one embodiment of a phone board 2000. The phone board 2000 includes the module 1900 shown in FIGS. 19A and 19B attached thereto. Although not illustrated in FIG. 20 for clarity, the phone board 2000 can include additional components and structures.

### Applications

Some of the embodiments described above have provided examples in connection with wireless devices or mobile phones. However, the principles and advantages of the embodiments can be used for any other systems or apparatus that have needs for power amplifiers.

Such embodiments can be implemented in various electronic devices. Examples of the electronic devices can include, but are not limited to, consumer electronic products, parts of the consumer electronic products, electronic test equipment, etc. Examples of the electronic devices can also include, but are not limited to, memory chips, memory modules, circuits of optical networks or other communication networks, and disk driver circuits. The consumer electronic products can include, but are not limited to, a mobile phone, a telephone, a television, a computer monitor, a computer, a hand-held computer, a personal digital assistant (PDA), a microwave, a refrigerator, an automobile, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A Doherty power amplifier system comprising:
a plurality of amplifiers including a main amplifier configured to amplify a first radio frequency input signal to generate a first radio frequency output signal, a first auxiliary amplifier configured to amplify a second radio frequency input signal to generate a second radio frequency output signal, and a second auxiliary amplifier configured to amplify a third radio frequency input signal to generate a third radio frequency output signal;
a first balun combiner configured to combine the second radio frequency output signal and the third radio frequency output signal to generate a first radio frequency combined signal; and
a second balun combiner configured to combine the first radio frequency output signal and the first radio frequency combined signal to generate a second radio frequency combined signal, the second balun combiner having an impedance ratio different than an impedance ratio of the first balun combiner.

2. The Doherty power amplifier system of claim 1 further comprising a bias circuit configured to selectively turn on or off the first auxiliary amplifier and the second auxiliary amplifier based on an envelope signal.

3. The Doherty power amplifier system of claim 1 wherein the impedance ratio of the second balun combiner is greater than the impedance ratio of the first balun combiner.

4. The Doherty power amplifier system of claim 3 wherein the impedance ratio of the first balun combiner is about three to one.

5. The Doherty power amplifier system of claim 4 wherein the impedance ratio of the second balun combiner is about two to one.

6. The Doherty power amplifier system of claim 1 further comprising an input splitting circuit configured to split a radio frequency input signal into the first radio frequency input signal, the second radio frequency input signal, and the third radio frequency input signal.

7. The Doherty power amplifier system of claim 1 wherein the first radio frequency input signal lags the second radio frequency input signal by about ninety degrees.

8. The Doherty power amplifier system of claim 1 wherein the third radio frequency input signal lags the second radio frequency input signal by about ninety degrees.

9. The Doherty power amplifier system of claim 1 wherein the first balun combiner includes a first input port that receives the second radio frequency output signal, a second input port that receives the third radio frequency output signal, an output port that provides the first radio frequency combined signal, an isolation capacitor connected between the first input port and an isolated node, an output capacitor connected between the second input port and the output port, and a balun having a first conductor connected between the first input port and the output port and a second conductor connected between the isolated node and the second input port.

10. The Doherty power amplifier system of claim 9 wherein the first balun combiner further includes a termination capacitor connected between the isolated node and ground.

11. The Doherty power amplifier system of claim 9 wherein the first balun combiner further includes a third conductor connected in parallel with the second conductor, the second conductor and the third conductor each magnetically coupled to the first conductor.

12. The Doherty power amplifier system of claim 11 wherein the second conductor and the third conductor are magnetically coupled to the first conductor with opposite coupling polarity.

13. A method of radio frequency signal amplification, the method comprising:
amplifying a first radio frequency input signal to generate a first radio frequency output signal using a main amplifier;
amplifying a second radio frequency input signal to generate a second radio frequency output signal using a first auxiliary amplifier;
amplifying a third radio frequency input signal to generate a third radio frequency output signal using a second auxiliary amplifier;
combining the second radio frequency output signal and the third radio frequency output signal to generate a first radio frequency combined signal using a first balun combiner; and
combining the first radio frequency output signal and the first radio frequency combined signal to generate a second radio frequency combined signal using a second balun combiner, the second balun combiner having an impedance ratio different than an impedance ratio of the first balun combiner.

14. The method of claim 13 further comprising selectively turning on or off the first auxiliary amplifier and the second auxiliary amplifier based on an envelope signal using a bias circuit.

15. A radio frequency communication system comprising:
a front end system including a main amplifier configured to amplify a first radio frequency input signal to generate a first radio frequency output signal, a first auxiliary amplifier configured to amplify a second radio frequency input signal to generate a second radio frequency output signal, a second auxiliary amplifier configured to amplify a third radio frequency input signal to generate a third radio frequency output signal, a first balun combiner configured to combine the second radio frequency output signal and the third radio frequency output signal to generate a first radio frequency combined signal, and a second balun combiner configured to combine the first radio frequency output signal and the first radio frequency combined signal to generate a second radio frequency combined signal, the second balun combiner having an impedance ratio different than an impedance ratio of the first balun combiner; and
an antenna configured to transmit the second radio frequency combined signal.

16. The radio frequency communication system of claim 15 wherein the front end system further includes a bias circuit configured to selectively turn on or off the first auxiliary amplifier and the second auxiliary amplifier based on an envelope signal.

17. The radio frequency communication system of claim 15 wherein the impedance ratio of the second balun combiner is greater than the impedance ratio of the first balun combiner.

18. The radio frequency communication system of claim 15 wherein the front end system includes an input splitting circuit configured to split a radio frequency input signal into the first radio frequency input signal, the second radio frequency input signal, and the third radio frequency input signal.

19. The radio frequency communication system of claim 18 further comprising a transceiver configured to generate the radio frequency input signal.

20. The radio frequency communication system of claim 15 wherein the first balun combiner includes a first input port that receives the second radio frequency output signal, a second input port that receives the third radio frequency output signal, an output port that provides the first radio frequency combined signal, an isolation capacitor connected between the first input port and an isolated node, an output capacitor connected between the second input port and the output port, and a balun having a first conductor connected between the first input port and the output port and a second conductor connected between the isolated node and the second input port.
